(19) United States
(12) Patent Application Publication
(10) Pub. No.: US 2025/0086362 A1
(43) Pub. Date: Mar. 13, 2025

(54) SYSTEM CONFIGURATION EVALUATION APPARATUS, SYSTEM CONFIGURATION EVALUATION METHOD, AND COMPUTER-READABLE RECORDING MEDIUM

(71) Applicant: NEC Corporation, Tokyo (JP)

(72) Inventors: Yutaka YAKUWA, Tokyo (JP); Takayuki KURODA, Tokyo (JP)

(73) Assignee: NEC Corporation, Tokyo (JP)

(21) Appl. No.: 18/822,681

(22) Filed: Sep. 3, 2024

(30) Foreign Application Priority Data
Sep. 7, 2023 (JP) 2023-145331

(51) Int. Cl. G06F 30/27

(52) U.S. Cl. CPC G06F 30/27

(57) ABSTRACT

A system configuration evaluation apparatus includes: a configuration evaluation unit configured to output, using a learning model, evaluation values of configuration elements of a computer system, and further output an evaluation value of the entire computer system obtained by integrating the output evaluation values; and a configuration element learning unit configured to trial design of the computer system based on preset requirements, determine, with respect to configurations obtained throughout the designing from start to finish, whether or not configuration elements included in the configurations are concretized according to the requirements, generate training data for the learning model based on a determination result, and execute machine learning on the learning model using the generated training data.

### CROSS-REFERENCE TO RELATED APPLICATION

This application is based upon and claims the benefit of priority from Japanese patent application No. 2023-145331, filed on Sep. 7, 2023, the disclosure of which is incorporated herein in its entirety by reference.

### TECHNICAL FIELD

The present disclosure relates to technologies for automated design of an Information and Communication Technology (ICT) system and machine learning thereof. The present disclosure particularly relates to a system design automation technology for realizing design automation by humans declaratively defining only requirements of the design and components to be used, causing a computer to calculate the scope of conceivable design as a design space based on the definition, and causing Artificial Intelligence (AI) to search the space, as well as to a technology for machine learning thereof.

### BACKGROUND ART

Patent Document 1 discloses a technology for automated design of an ICT system that satisfies requirements of a client. With the technology disclosed in Patent Document 1, a system configuration in which abstract elements contained in abstract system requirements of the client are concretized in a stepwise manner and are detailed to a deployable level is derived.

Also, in the technology disclosed in Patent Document 1, the client's abstract “system requirements” (or simply “requirements”), “system configuration draft” (or simply “configuration draft”) while the system requirements are being concretized, and “concrete system configuration” (or simply “concrete configuration”) when the system requirements are fully concretized are represented by the graph illustrated in FIG. 42. FIG. 42 is a diagram illustrating an example of a graph of requirements of an ICT system. FIG. 43 is a diagram illustrating configuration elements included in the requirements of the ICT system illustrated in FIG. 42.

Also, the three items, namely, the system requirements, the system configuration draft, and the concrete system configuration are collectively referred to as “system configuration” (or simply “configuration”). Nodes and edges constituting a graph of a system configuration are referred to as configuration elements. A node means an individual component (such as, for example, a server or a router) included in the system configuration, and an edge mean a relationship (such as, for example, network connection) between components.

Concretization is realized by rewriting a graph. A rule for how to rewrite a graph is prepared in advance before performing automated design, and the rule is referred to as a concretization rule. A plurality of applicable concretization rules (i.e., rules for how to rewrite a graph) may be prepared for system requirements and system configuration drafts. The design is branched and the concrete configuration of a system to be derived is changed according to which concretization rule is applied and the order of application thereof. As a result, there is also a situation in which a difference occurs in design and, in some cases, the design fails (input system requirements are not satisfied).

Therefore, to perform efficient design using the technology disclosed in Patent Document 1, it is important to determine which of the above-described plurality of applicable concretization rules are to be applied, as described above, and determine whether or not the order of application of the concretization rules is appropriate.

Non-Patent Document 1 discloses a technology for determining, using reinforcement learning, which of the above-described concretization rules are to be applied and whether or not the order is appropriate, as described above. Reinforcement learning is a technology in which, in problems where obtained results differ according to the content and order of actions, various trials are repeated and determinations of whether or not the content and order of actions are appropriate are learned based on rewards obtained according to the results of the trials. Reinforcement learning has achieved high performance results in learning of Go game AI and the like. Also, Patent Document 2 discloses a technology for learning evaluations of partial elements of a system configuration.

### LIST OF RELATED ART DOCUMENTS

### Patent Documents

Patent Document 1: Japanese Patent No. 7036205
Patent Document 2: Japanese Patent Laid-Open Publication No. 2022-63209

### Non-Patent Document

Non-Patent Document 1: Takashi Maruyama, et al. “Accelerated Search for Search-Based Network Design Generation Scheme with Reinforcement Learning” IEICE Technical Report, vol. 118, no. 483, ICM2018-71, pp. 123-128, 2019 March

### SUMMARY OF INVENTION

### Problems to be Solved by the Invention

Meanwhile, the technology disclosed in Patent Document 1 has two problems caused by the fact that system configuration evaluation is given for the overall system configuration. The first problem is that when some of the configurations are changed, learned content cannot be applied due to the impact of the change being unknown. The second problem is that the amount of data and time required for learning increase with the size of the system configuration and is not scalable.

Even when the technology disclosed in Patent Document 2 is used, it is difficult to solve the above-described two problems because the learning target in the technology disclosed in Patent Document 1 is still an evaluation of the probability of success of design of the overall system configuration, and learning processing needs to be performed in units of system configurations.

### SUMMARY OF THE INVENTION

An example object of the present disclosure is to be able to apply learned content even when part of a system configuration is changed, and to suppress an increase in the amount of data and time required for learning with the size of the system configuration.

In order to achieve the above-described object, a system configuration evaluation apparatus includes:
a configuration evaluation unit configured to output, using a learning model, evaluation values of configuration elements of a computer system, and further output an evaluation value of the entire computer system obtained by integrating the output evaluation values; and
a configuration element learning unit configured to trial design of the computer system based on preset requirements, determine, with respect to configurations obtained throughout the designing from start to finish, whether or not configuration elements included in the configurations are concretized according to the requirements, generate training data for the learning model based on a determination result, and execute machine learning on the learning model using the generated training data.

In order to achieve the above-described object, a system configuration evaluation method includes:
a configuration evaluation step of outputting, using a learning model, evaluation values of configuration elements of a computer system, and further outputting an evaluation value of the entire computer system obtained by integrating the output evaluation values; and
a configuration element learning step of trialing design of the computer system based on preset requirements, determining, with respect to configurations obtained throughout the designing from start to finish, whether or not configuration elements included in the configurations are concretized according to the requirements, generating training data for the learning model based on a determination result, and executing machine learning on the learning model using the generated training data.

In order to achieve the above-described object, a computer readable recording medium according to an example aspect of the invention is a computer readable recording medium that includes recorded thereon a program,
the program including instructions that cause the computer to carry out:
a configuration evaluation step of outputting, using a learning model, evaluation values of configuration elements of a computer system, and further outputting an evaluation value of the entire computer system obtained by integrating the output evaluation values; and
a configuration element learning step of trialing design of the computer system based on preset requirements, determining, with respect to configurations obtained throughout the designing from start to finish, whether or not configuration elements included in the configurations are concretized according to the requirements, generating training data for the learning model based on a determination result, and executing machine learning on the learning model using the generated training data.

As described above, according to the invention, it is possible to apply learned content even when part of a system configuration is changed, and to suppress an increase in the amount of data and time required for learning with the size of the system configuration.

### BRIEF DESCRIPTION OF THE DRAWINGS

FIG. 1 is a configuration diagram illustrating a schematic configuration of an example of the system configuration evaluation apparatus.

FIG. 2 is a configuration diagram illustrating the configuration of an example of the system configuration evaluation apparatus in more details.

FIG. 3 is a flow chart illustrating an example of a learning operation of configuration evaluation in an example (first example) of a system configuration evaluation apparatus.

FIG. 4 is a flow chart illustrating an operation (step S12) during one time of the reinforcement learning repeatedly performed illustrated in FIG. 3.

FIG. 5 is a flow chart illustrating an operation of generating a configuration path from system requirements in the reinforcement learning illustrated in FIG. 4 (step S121).

FIG. 6 is a flow chart illustrating an operation of generating learning data in the reinforcement learning illustrated in FIG. 4 (step S122).

FIG. 7 is a flow chart illustrating an operation (step B11) for determining whether or not the configuration element illustrated in FIG. 6 is “completely specific”.

FIG. 8 is a flow chart illustrating an operation of performing learning using learning data in the reinforcement learning illustrated in FIG. 4 (step S124).

FIG. 9 is a flow chart illustrating an operation (step S13) for performing a design trial in the reinforcement learning illustrated in FIG. 3.

FIG. 10 is a flow chart illustrating an operation of configuration evaluation in the system configuration evaluation apparatus.

FIG. 11 is a configuration diagram illustrating a configuration of an example (second example) of a system configuration evaluation apparatus.

FIG. 12 is a flow chart illustrating an operation of initial learning of configuration evaluation in an example (second example) of a system configuration evaluation apparatus.

FIG. 13 is a flow chart illustrating an operation (step U21) of generating a dependency graph in the initial learning of the configuration evaluation illustrated in FIG. 12.

FIG. 14 is a flow chart illustrating an operation (step U22) of generating a curriculum in the initial learning of the configuration evaluation illustrated in FIG. 12.

FIG. 15 is a flow chart illustrating an operation (step U224) of calculating the learning difficulty level in the curriculum generation illustrated in FIG. 14.

FIG. 16 is a flow chart illustrating an operation (step U227) of deleting an edge and eliminating a cycle in the curriculum generation illustrated in FIG. 14.

FIG. 17 is a flow chart illustrating an operation (step D23) of generating a deletion candidate list of edges included in a cycle in the curriculum generation illustrated in FIG. 16.

FIG. 18 is a flow chart illustrating an operation (step D24) of selecting and deleting one edge from the deletion candidate list in the curriculum generation illustrated in FIG. 16.

FIG. 19 is a flow chart illustrating an operation (step U25) of generating a set of requirements used for learning of learning items in initial learning of the configuration evaluation illustrated in FIG. 12.

FIG. 20 is a flow diagram illustrating an operation (step U257) of recursively processing configuration elements included in a configuration necessary for materialization of a materialization rule or a configuration after materialization in the operation of generating a set of requirements used for learning of learning items illustrated in FIG. 19.

FIG. 21 is a flow chart illustrating an operation (step U26) of learning a learning item using a set of requirements in the initial learning of the configuration evaluation illustrated in FIG. 12.

FIG. 22 is a flow chart illustrating an operation of relearning of configuration evaluation in an example (second example) of a system configuration evaluation apparatus.

FIG. 23 is a configuration diagram illustrating a configuration of an example (third example) of a system configuration evaluation apparatus.

FIG. 24 is a flow chart illustrating an operation of a design in an example (third example) of a system configuration evaluation apparatus.

FIG. 25 is a configuration diagram illustrating a configuration of an example (fourth example) of a system configuration evaluation apparatus.

FIG. 26 is a flow chart illustrating an operation of learning in an example (fourth example) of the system configuration evaluation apparatus.

FIG. 27 is a flow chart illustrating an operation in a period of one time of the reinforcement learning repeatedly performed illustrated in FIG. 26.

FIG. 28 is a flow chart illustrating an operation of generating a configuration path from system requirements in the reinforcement learning illustrated in FIG. 27 (step S421).

FIG. 29 is a flow chart illustrating an operation of design in an example (fourth example) of a system configuration evaluation apparatus.

FIG. 30 is a diagram illustrating a state in which design is repeatedly branched and configurations are generated in automatic design of an ICT system.

FIG. 31 is a diagram illustrating information representing an ICT system configuration in a graph structure in automatic design of an ICT system.

FIG. 32 is a diagram illustrating information in which the system configuration of the ICT system illustrated in FIG. 31 is expressed by text.

FIG. 33 is a diagram illustrating a format for defining configuration element types in automatic design of an ICT system.

FIG. 34 is a diagram illustrating an example of a dependency graph generated in second example embodiment.

FIG. 35 is a diagram illustrating an example of a curriculum generated in the second example embodiment.

FIG. 36 is a diagram illustrating an example of a configuration pass.

FIG. 37 is a diagram illustrating an example of a search tree generated in the first example embodiment.

FIG. 38 is a diagram illustrating a format for defining configuration element types in automatic design of an ICT system.

FIG. 39 is a diagram illustrating an example of configuration element type definition information which is information representing a definition of a type of a configuration element in automatic design of an ICT system.

FIG. 40 is a diagram illustrating an example of materialization rule definition information which is information representing a definition of a materialization rule generated from the configuration element type definition information of FIG. 39 in automatic design of an ICT system.

FIG. 41 is a block diagram illustrating an example of a computer that realizes the system configuration evaluation apparatus.

FIG. 42 is a diagram illustrating an example of a graph of requirements of an ICT system.

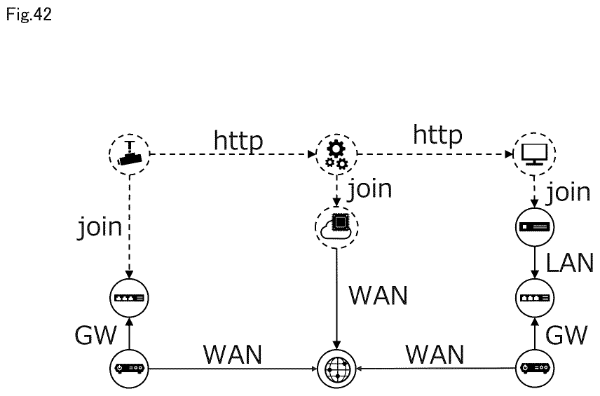

FIG. 43 is a diagram illustrating configuration elements included in the requirements of the ICT system illustrated in FIG. 42.

### EXAMPLE EMBODIMENTS

### (Disclosure Presupposition)

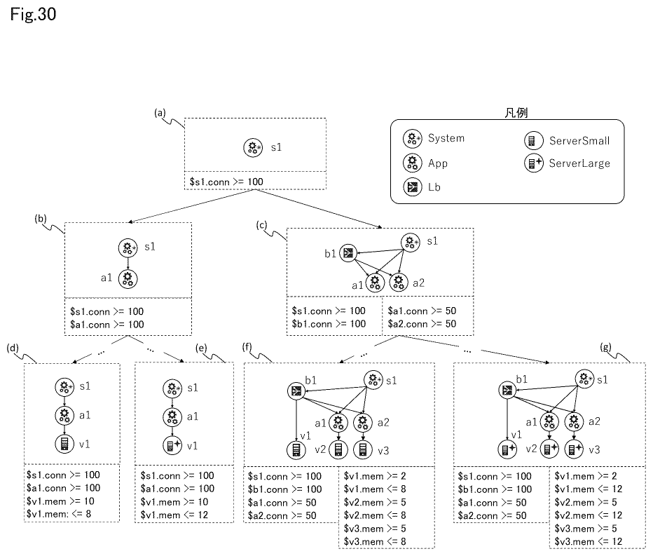

Before describing example embodiments, the automated design of an ICT system to which the present invention is applied is described. First, a state in which design is repeatedly branched and configurations are generated is illustrated in FIG. 30. In FIG. 30, (a) to (g) each represent a configuration of an ICT system. Each configuration may include, in addition to information on a graph indicating the ICT system configuration itself, information on constraint conditions imposed on configuration elements. Constraint conditions are conditions, expressed as equations and inequalities, that are to be satisfied by the evaluation indices of configuration elements.

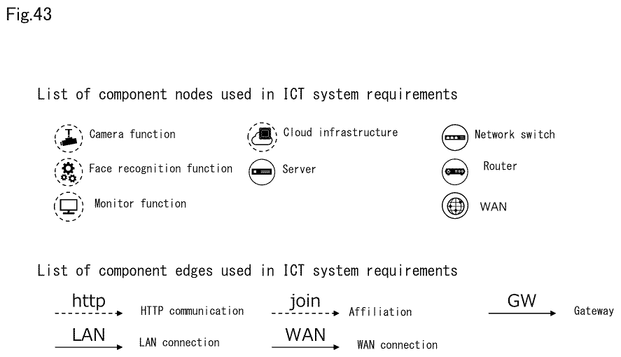

As illustrated in FIG. 30, among information contained in each configuration (portion delimited by a rectangle in FIG. 30), a node expressed by a circle is an individual part (e.g., a server, a router, etc.) contained in the system configuration, and denotes a component part. An edge represented by an arrow denotes the relationship (e.g., network connection, etc.) between components. As described above, nodes and edges are referred to as “configuration elements”. An icon of each component part denotes the type of the component part. The correspondence between the icons and the types is illustrated as explanatory notes (see FIG. 43). A character string added to a component part denotes the identifier of the component part. Also, an inequality added to each configuration expresses a constraint condition. For example, “$s1.conn>=100” is a constraint condition relating to an evaluation index “conn” associated with the configuration whose identifier is “s1”, and expresses that “conn” is 100 or more.

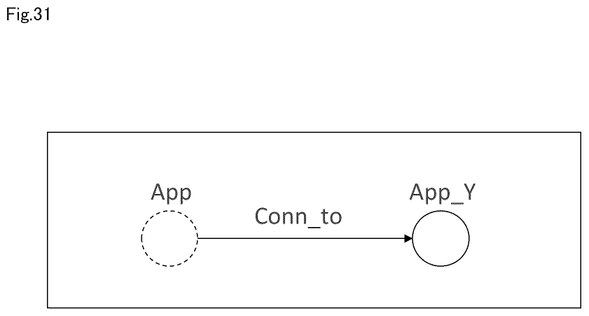

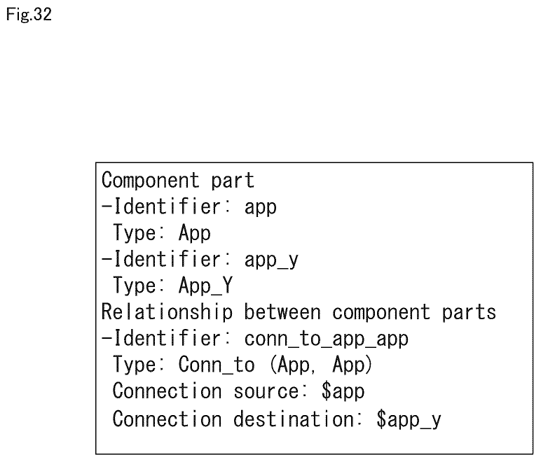

Information (hereinafter referred to as “configuration information”) contained in each configuration is not limited to information represented by the diagram illustrated in FIG. 30 and may be information represented by text. The representation method using text is not particularly limited as long as the information can be converted into a unique diagram, and as an example thereof, FIG. 32 illustrates an example in which the configuration illustrated in FIG. 31 is represented by text.

In FIG. 31, text added to the nodes and the edge indicates component parts and the relationship between the component parts. That is, FIG. 31 illustrates a configuration in which a specific application Y and some sort of application can communicate with each other, and expresses, using the nodes and the edge, that “App and App_Y are connected to each other with a relationship of Conn_to”. A dotted line represents an abstract component part, and a solid line represents a concrete component part. App is an abstract node representing some sort of application and is indicated by a dotted line at this point in time, and in the process of concretization of the configuration, App will be concretized to a specific application.

As illustrated in FIG. 32, the configuration information in a text format includes a list of the component part and the relationship between the component parts. For each component part, an identifier for identifying the component part and the type of the component part are defined. For each relationship, an identifier for identifying the relationship, the type of the relationship, the identifier of a component part serving as a connection source, and the identifier of a component part serving as a connection destination are defined. “$” in FIG. 32 denotes reference to the identifier to which it is added. If the definition of the identifier of a component part is not needed due to being not referenced by another definition part of the component part, the definition of the identifier may be omitted.

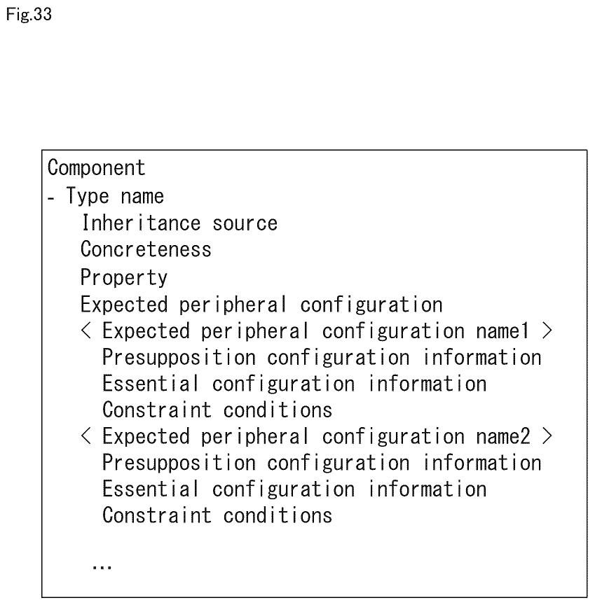

The following will describe how to define the types of configuration elements indicating a node and an edge. FIG. 33 illustrates a format for defining the type of configuration element. For the type of configuration element, information indicating characteristics of the type of the configuration element, such as the name (type name), inheritance source, concreteness, and properties of the type of the configuration element are designated. Also, for the type of configuration element, information on an expected peripheral configuration is designated. An expected peripheral configuration is information on a configuration that is expected to be present in the periphery of the configuration element of this type in order for the configuration element to be present within a system configuration. Note that the type of configuration element is also referred to as “configuration element type”. Also, data defining a configuration element type and the like is also referred to as “configuration element type definition information”.

The above-described inheritance source refers to the type of another configuration element that the corresponding configuration element inherits, and if there is no designation, this means that the configuration element does not inherit any configuration element. As a result of a component part inheriting the type of another component part and the relationship between component parts inheriting the type of another relationship between other component parts, the property of the type of the inheritance source and information on expected peripheral configurations can be inherited.

The above-described concreteness is a flag indicating whether the configuration element type itself is the type of an abstract configuration element that can further be concretized, or is the type of a concrete configuration element that can no longer be concretized. If the concreteness is True, it means that it is a concrete configuration element type. If the concreteness is False, it means that it is an abstract configuration element type, and can be concretized into another configuration element type that inherits this configuration element type.

The property refers to attribute information indicating characteristics of this configuration element type, and can designate arbitrary attribute information according to the sorts of configuration element types. The expected peripheral configuration refers to configuration information to be satisfied in the periphery of the configuration element of this type in order that the configuration element itself is established, and the expected peripheral configuration indicates that when the configuration described in the configuration information is present, the configuration element of this type is established.

For example, an OS that hosts some sort of application is considered to be essential for the application to exist, and thus in an expected peripheral configuration of an APP-type component part, configuration information that the APP itself is hosted by some sort of OS-type component part is described. A plurality of expected peripheral configurations can be defined for a single configuration element. If even one expected peripheral configuration of a configuration element exists in a configuration, it is expressed that the expected peripheral configuration of the configuration element is satisfied.

In individual expected peripheral configuration, the name, presupposition configuration information, essential configuration information, and constraint conditions of the expected peripheral configuration are described. Presupposition configuration information refers to configuration information that is presupposed when it is concretized to satisfy the later-described essential configuration information. Presupposition configuration information indicates that when the system configuration during design satisfies the configuration information described in the presupposition configuration information, the later-described essential configuration information is applied to concretize the system configuration. Essential configuration information is information for concretizing the system configuration by one stage by adding the configuration information described herein to the system configuration. Constraint conditions are constraint conditions to be satisfied by the configuration elements when the system configuration is concretized with the configuration information described in the essential configuration information.

Processing of concretizing the system configuration based on input system requirements includes processing of concretizing configuration elements to concrete configuration elements, and processing of concretizing the system configuration so that the expected peripheral configurations defined for the respective configuration elements are satisfied. Therefore, information on concretization rules can be generated from content of the inheritance source and the expected peripheral configuration, among the definitions of the configuration element type.

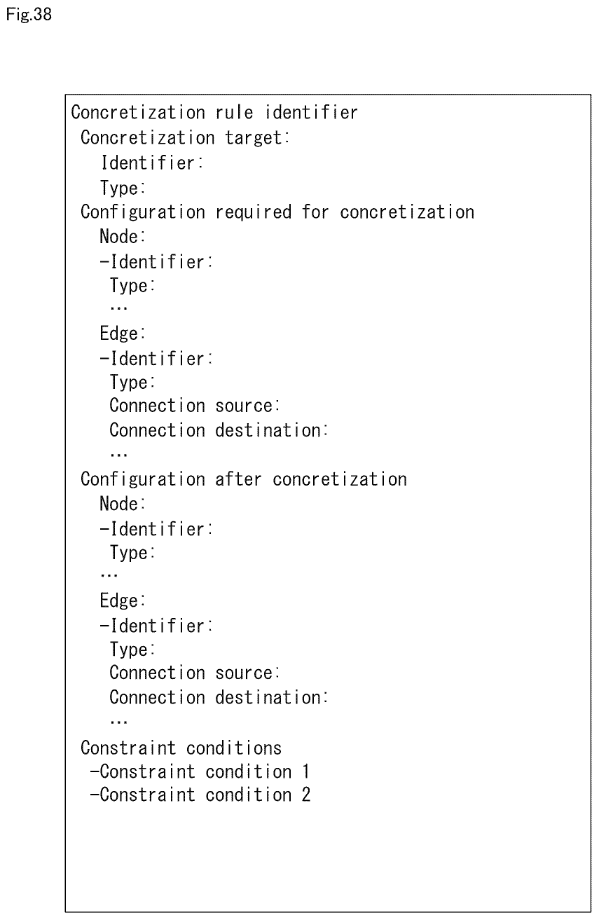

FIG. 38 illustrates a format for defining concretization rules. For the concretization rules, information on a concretization target, a configuration required for concretization, a configuration after concretization, and constraint conditions is designated. For the concretization target, the type name of a configuration element to serve as a concretization target is designated. The concretization rules are intended to concretize only one configuration element, and only one configuration element is concretized in a single application of the concretization rules.

For the configuration required for concretization, a peripheral configuration that needs to be satisfied in advance when applying the concretization rules is defined. That is, the concretization rules are applied only when the configuration indicated by the configuration required for concretization is present in the periphery of the configuration element to be concretized. The configuration after concretization designates a configuration that remains after the application of the concretization rules.

When the concretization rules are applied, the configuration element to be concretized will be replaced by the configuration indicated by the configuration after concretization. For the concretization rules, the conditions that need to be satisfied after the application of the concretization rules are designated. That is, the concretization rules are applied only when the concretization target and the configuration present in the periphery thereof can satisfy the content designated by the constraint conditions even after the application of the concretization rules.

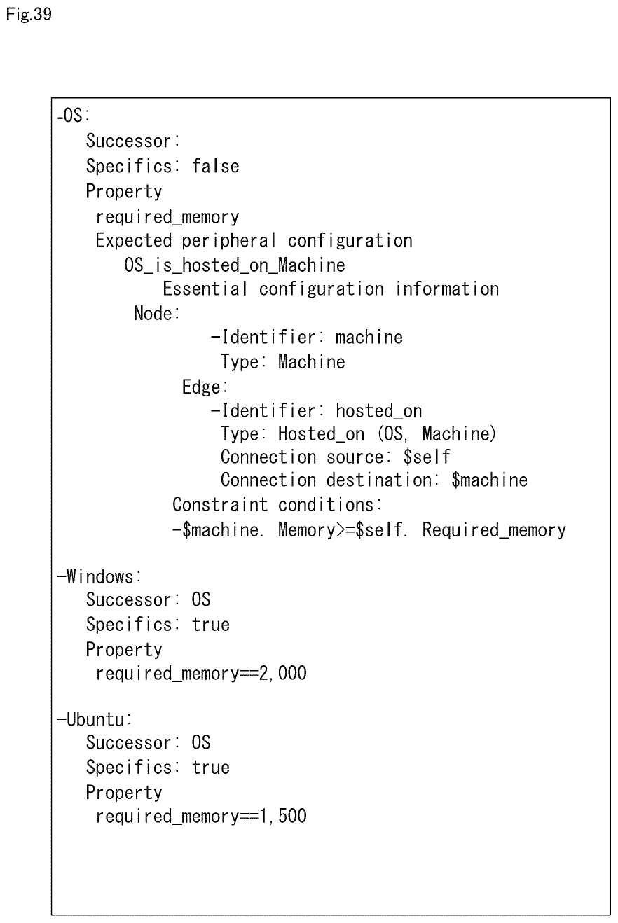

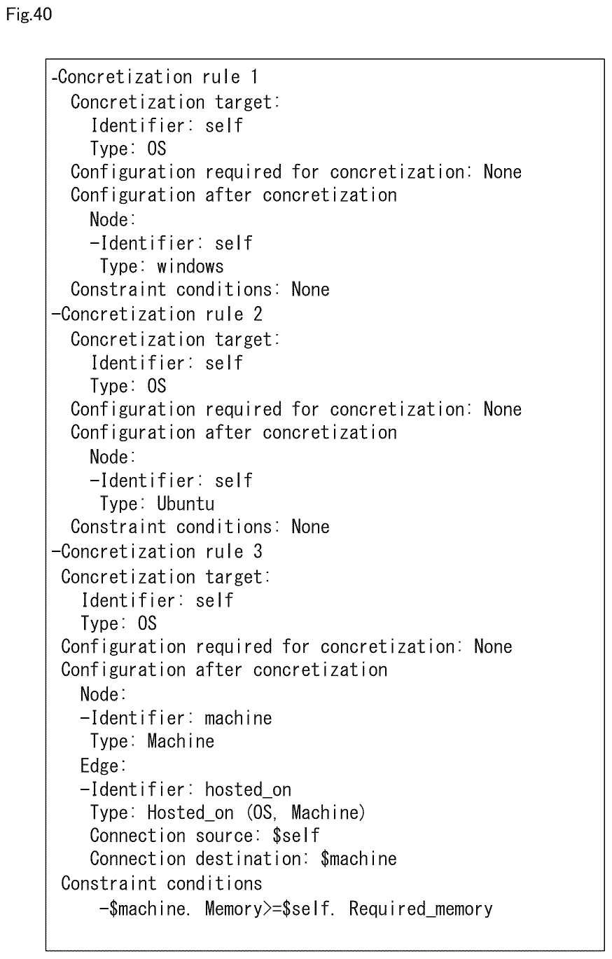

FIG. 39 illustrates examples of definitions of configuration element types. FIG. 40 illustrates examples of definitions of concretization rules that can be generated from the definitions of the configuration element types illustrated in FIG. 39. FIG. 39 illustrates examples of definitions of an OS, which is a type of abstract component part and indicates an operating system, and examples of definitions of Windows and Ubuntu, which are types that inherit the OS. The OS holds, as a property, required memory, which designates the amount of memory used by the OS. However, the OS-type is a type of abstract component part, and thus specific values are not set. Since the OS needs to be hosted on some sort of Machine in order to be established, it is defined, as an expected peripheral configuration, that a relationship of “Hosted_on” is to be established between the OS itself and the Machine.

Furthermore, as constraint conditions when the expected peripheral configuration is applied, it is defined that the amount of memory installed in the Machine, which is a host source, is greater than or equal to the amount of memory usage required by the OS itself. Also, the component parts of Windows-type and Ubuntu-type, which are specific OSs, are defined as the type that inherits the OS, and the concrete memory usage values are set.

FIG. 40 illustrates examples of definitions of three types of concretization rules for concretizing the OS. Concretization rule 1 defines a concretization rule for concretizing the abstract configuration element of the OS-type into the concrete configuration element of the Windows-type. Concretization rule 2 defines a concretization rule for concretizing the abstract configuration element of the OS-type into the concrete configuration element of the Ubuntu-type. Concretization rule 3 defines a concretization rule for concretizing the OS by generating a Machine-type component part and a Hosted_on-type relationship that connects the OS-type configuration element and the Machine-type configuration element, so that the expected peripheral configuration of the OS is satisfied. Note that data in which concretization rules are defined, as illustrated in FIG. 40, and the like are also referred to as “concretization rule definition information”.

When two types of processing, namely, the processing of concretizing each configuration element itself into a concrete configuration element, and the processing of concretizing a system configuration to satisfy expected peripheral configurations defined for each configuration element are completed for all configuration elements included in the system configuration, the system design is determined to be completed. That is, when the concreteness of all configuration elements within the system configuration are True and expected peripheral configurations of all the configuration elements are satisfied, it is determined that the system configuration is a concrete configuration and the design is completed. When a plurality of expected peripheral configurations are defined for a single configuration element, it is sufficient that one of the expected peripheral configurations is satisfied.

Also, when performing concretization of the system to satisfy an expected peripheral configuration of a certain configuration element, if all or some of configuration elements described in the configuration after concretization of the concretization rules that define the content of the concretization already exist in the system configuration, the system may be concretized into a configuration that uses existing configuration elements, or into a configuration to which new configuration elements are added.

For example, if an expected peripheral configuration of an App-type component part contains configuration information that the App itself will be hosted by a OS-type component part, a new OS may be added to the system configuration to satisfy the expected peripheral configuration of this App, or if, for example, an OS at which another App is already hosted is present in the system configuration, no new OS may be added but the configuration may be concretized so that the App is hosted by an existing OS.

In this way, when performing concretization to satisfy an expected peripheral configuration, it is possible to appropriately select concretization into a configuration that uses existing configuration elements, or concretization into a configuration to which new configuration elements are added. Accordingly, even when one concretization rule is applied to a configuration, there may be a plurality of patterns of the application method. The patterns of the application method are also referred to as “application patterns”.

### Example Embodiment 1

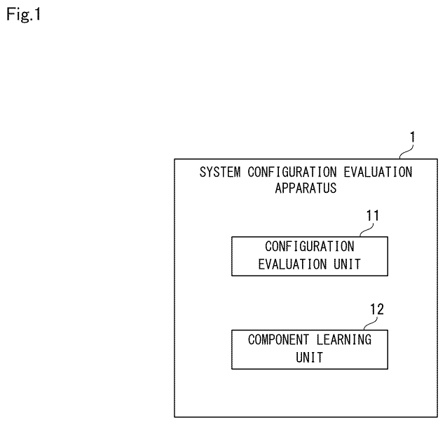

The following will describe a system configuration evaluation apparatus, a system 20) configuration evaluation method, and a program according to Example Embodiment 1 with reference to FIGS. 1 to 10.

### [Apparatus Configuration]

First, a schematic configuration of the system configuration evaluation apparatus according to Example Embodiment 1 is described with reference to FIG. 1. FIG. 1 is a configuration diagram illustrating a schematic configuration of an example of the system configuration evaluation apparatus.

The system configuration evaluation apparatus 1 illustrated in FIG. 1 is an apparatus that evaluates the configuration of a computer system such as an ICT system computer system. As illustrated in FIG. 1, the system configuration evaluation apparatus 1 includes a configuration evaluation unit 11 and a configuration element learning unit 12.

The configuration evaluation unit 11 outputs, using a learning model, evaluation values of configuration elements of the computer system, and further outputs an evaluation value of the entire computer system obtained by integrating the output evaluation values.

The configuration element learning unit 12 executes design of the computer system based on preset requirements, and determines whether or not configuration elements included in the configurations obtained throughout the designing from start to finish are concretized according to the requirements. The configuration element learning unit 12 also generates training data for the learning model based on results of the determination and executes machine learning on the learning model using the generated training data.

According to a first effect of the present invention, it is possible to solve the problem that when some of the configurations are changed, learned content cannot be applied due to the impact of the change being unknown, making application in units of configuration elements possible even when the overall configuration is changed. The reasons for this are as follows.

The system configuration evaluation apparatus 1 learns the probability of success of the concretization of each configuration element, instead of the probability of success of design of the overall system configuration. That is, the system configuration evaluation apparatus 1 generates a reward based on success of the concretization of each configuration element, and learns an evaluation that represents the probability that the concretization will be successfully completed for each configuration element based on the reward. Thus, according to the system configuration evaluation apparatus 1, learning in units of configuration elements is possible, and even when some of the system configurations are changed, learned content can be applied. Furthermore, according to the system configuration evaluation apparatus 1, the amount of data and time required for learning do not depend on the size of the configuration, and thus the amount of data and time required for learning are suppressed from increasing according to the size of the system configuration, leading to an improvement in learning efficiency.

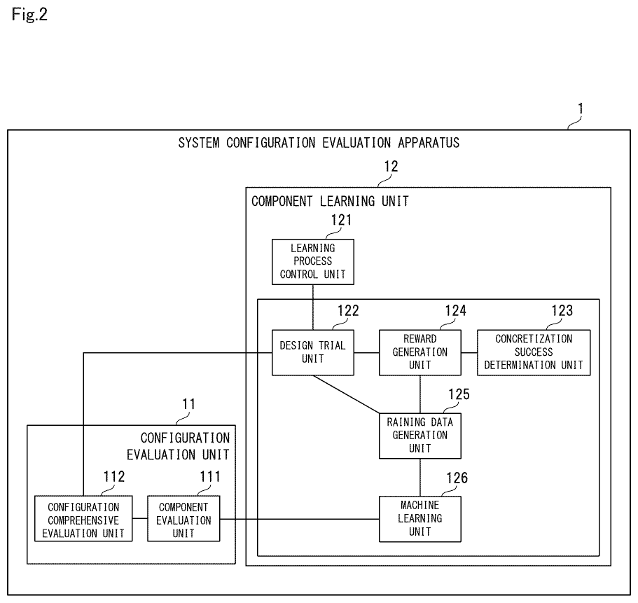

Subsequently, the configuration and function of the system configuration evaluation apparatus according to Example Embodiment 1 are specifically described with reference to FIG. 2. FIG. 2 is a configuration diagram illustrating the configuration of an example of the system configuration evaluation apparatus in more details. As illustrated in FIG. 2, the system configuration evaluation apparatus 1 includes, as described above, the configuration evaluation unit 11 and the configuration element learning unit 12.

Furthermore, as illustrated in FIG. 2, the configuration evaluation unit 11 includes a configuration element evaluation unit 111 and a configuration comprehensive evaluation unit 112. The configuration element learning unit 12 includes a learning process control unit 121, a design trial unit 122, a concretization success determination unit 123, a reward generation unit 124, a training data generation unit 125, and a machine learning unit 126. These units operate substantially as follows.

The configuration element evaluation unit 111 uses a learning model to output evaluation values of configuration elements contained in a configuration input to the learning model. Each evaluation value represents the probability of success as to whether or not the corresponding configuration element can be fully concretized. Also, the configuration comprehensive evaluation unit 112 integrates the evaluation values of the configuration elements output from the configuration element evaluation unit 111, and outputs the resultant evaluation value as the evaluation value of the overall configuration of the computer system.

The learning process control unit 121 performs overall control on learning processes of the learning model. The design trial unit 122 trials design of the computer system, and collects configurations obtained throughout the designing from start to finish.

The concretization success determination unit 123 determines whether or not the configuration elements contained in the configurations resulting from the design of the design trial unit 122 have been fully concretized according to the requirements. The reward generation unit 124 calculates rewards to be given to the respective configuration elements contained in the collected configurations based on the results of the determination by the concretization success determination unit 123.

The training data generation unit 125 generates, for each of the collected configurations, the configuration and the rewards to be given to the configuration elements calculated for the configuration, as training data. The machine learning unit 126 uses the generated training data to train the learning model to be used by the configuration element evaluation unit 111 with the evaluation values representing whether or not the configuration elements can be fully concretized.

### [Apparatus Operations]

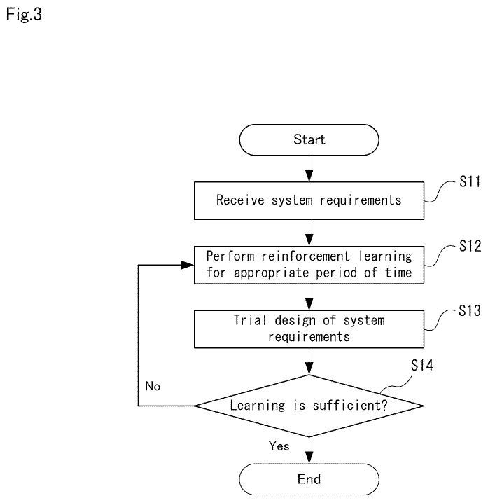

The following will describe an example of the operations of the system configuration evaluation apparatus 1 according to Example Embodiment 1 with reference to FIGS. 3 to 10. In the following description, FIGS. 1 and 2 are referenced as appropriate. Also, in Example Embodiment 1, a system configuration evaluation method is executed by operating the system configuration evaluation apparatus 1. Accordingly, in Example Embodiment 1, description of the system configuration evaluation method is replaced with the following description on the operation of the system configuration evaluation apparatus.

In Example Embodiment 1, the operations of the system configuration evaluation apparatus 1 are broadly divided into two operations. One is a configuration evaluation learning operation, and the other is configuration evaluation operation. In the configuration evaluation learning operation, the system configuration evaluation apparatus 1 executes training of the learning model relating to evaluation of the computer system in units of configuration elements to evaluate configurations of the computer system (ICT system). In the configuration evaluation operation, the system configuration evaluation apparatus 1 uses the trained learning model to execute evaluation of the computer system configuration. The following will describe the operations.

A configuration evaluation learning operation S1 in the system configuration evaluation apparatus 1 will be described in detail with reference to FIG. 3. First, the learning process control unit 121 receives system requirements R1 to be learned as an input (step S11).

Then, the configuration element learning unit 12 performs reinforcement learning for an appropriate period of time using the system requirements R1 (step S12). An appropriate period of time may be determined based on learning time, the number of times of learning, and in the case 10) of, e.g., reinforcement learning using a neural network, the number of updates of the weight of the neural network, and the like, but may also be determined based on other factors.

Furthermore, the design trial unit 122 trials design of the system requirements R1 using the current learning model (in the case of reinforcement learning using, e.g., a neural network, the neural network) (step S13). As the design method in this case, the design method disclosed in Patent Document 1 is exemplified. However, in the example embodiment, the design method is not particularly limited.

Then, based on the result of step S13, the learning process control unit 121 determines whether or not learning is sufficient (step S14). The determination method in step S14 depends on the design method in step S13. For example, it is assumed that step S13 is executed by the design method disclosed in Patent Document 1. In this case, examples of the method include a method that determines learning is sufficient when the number of searching steps in design is less than a predetermined number, and a method that determines learning is sufficient when, in design in step S13 executed in the past, the number of searching steps is less than the predetermined number for a specified number of times in a row. However, in the example embodiment, the determination method in step S14 is not particularly limited.

If the result of the determination in step S14 indicates that the learning is not sufficient, steps S12 and S13 are executed again. On the other hand, if the result of the determination in step S14 indicates that the learning is sufficient, the learning operation S1 is ended.

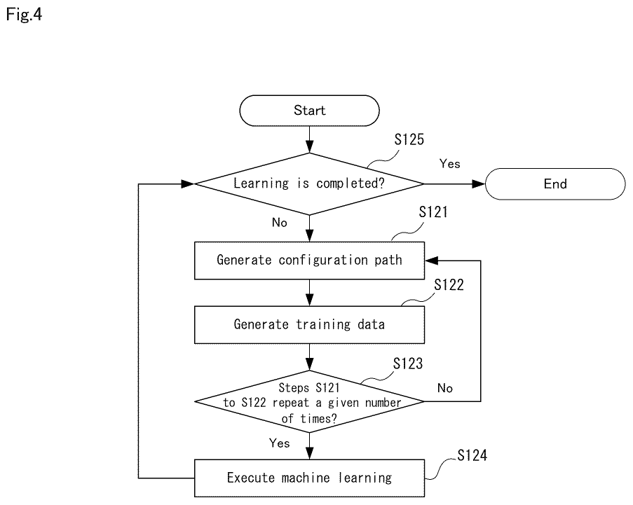

The operation of step S12 of performing reinforcement learning is described in detail with reference to FIG. 4. The operation to be described here is an example of an operation of learning design methods regarding the functional requirements of the system. The operation in step S12 is not limited to the operation described here as long as the learning of design methods regarding the functional requirements of the system is realized. Also, an example of the design method is the design method disclosed in Patent Document 1 as described above, but the present invention is not limited to this.

As illustrated in FIG. 4, first, the design trial unit 122 trials design using the system requirements R1 and generates a configuration path CP1 (step S121). Then, the training data generation unit 125 generates training data (step S122). Subsequently, the design trial unit 122 determines whether or not steps S121 to S122 have been repeated a given number of times (step S123).

The given number of times in this context is determined as appropriate based on the size of the training data, the number of pieces of training data that can be generated in one iteration, specifications of a machine used for learning, and the like. Note that in the example embodiment, the given number of times may be determined based on other factors.

If the result of the determination in step S123 indicates that steps S121 to S122 are not repeated the given number of times, the design trial unit 122 executes step S121 again. On the other hand, if the result of the determination in step S123 indicates that steps S121 to S122 are repeated the given number of times, the machine learning unit 126 executes machine learning on the learning model using the training data (step S124).

Then, the machine learning unit 126 determines whether or not the learning is completed, that is, whether or not the learning has been executed for an appropriate period of time (step S125). If the result of the determination in step S125 indicates that the learning is not completed, steps S121 to S124 are executed again. On the other hand, if the result of the determination in step S125 indicates that the learning is completed, step S12 is ended.

The appropriate period of time in this context may be determined based on learning time, the number of times of learning, and in the case of reinforcement learning using, e.g., a neural network, the number of updates of the weight of the neural network. However, in Example Embodiment 1, the appropriate period of time may be determined based on other factors.

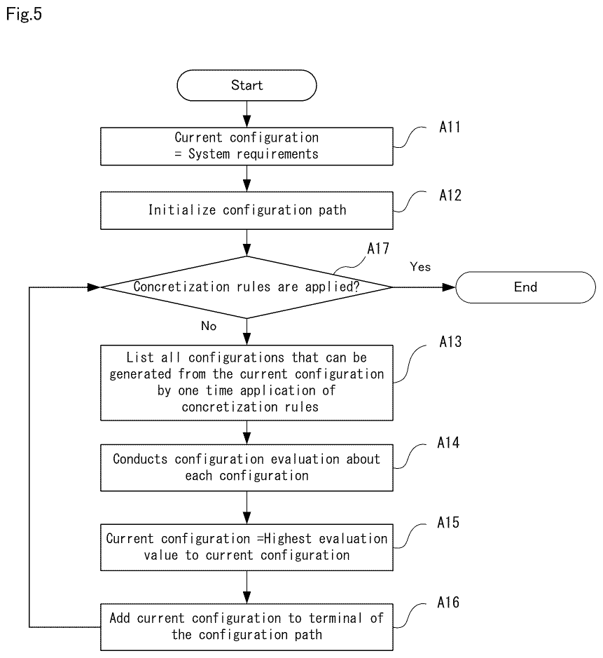

The operation of step S121 of generating a configuration path is described in detail with reference to FIG. 5. The unit that performs the operation in step S121 is the design trial unit 122 unless otherwise noted. First, the design trial unit 122 assigns the system requirements R1 to a variable representing the current configuration (step A11). Hereinafter, content assigned to the variable representing the current configuration is expressed simply by “current configuration”.

Then, the design trial unit 122 initializes the configuration path CP1 as a variable in a list type data structure containing only the current configuration as content (step A12). The configuration path CP1 is a variable that holds the process of configuration during design and is obtained as a result of the trials of design conducted to generate the training data. Note here that a case where the data structure of the configuration path CP1 is of the list type is given as an example, but the data structure may be of any type other than the list type as long as it is a data structure that can store multiple contents of the same type in a definite order.

Furthermore, the design trial unit 122 lists all configurations that can be generated from the current configuration by one time application of concretization rules (step A13). Then, the design trial unit 122 inputs the configurations listed in step A13 to the configuration comprehensive evaluation unit 112, and conducts configuration evaluation (step A14). A configuration evaluation operation T1 will be described in detail later.

Then, the design trial unit 122 assigns, among the configurations for which the configuration evaluation has been executed in the processing in step A14, the highest evaluation value to the variable representing the current configuration (step A15). Then, the design trial unit 122 adds the current configuration to the terminal of the configuration path CP1 (step A16).

Then, the design trial unit 122 determines whether or not the concretization rules can be applied to the current configuration (step A17). If the result of the determination in step A17 indicates that the concretization rules can be applied, the design trial unit 122 executes steps A13 to A16 again. On the other hand, if the result of the determination in step A17 indicates that the concretization rules cannot be applied, step S121 is ended.

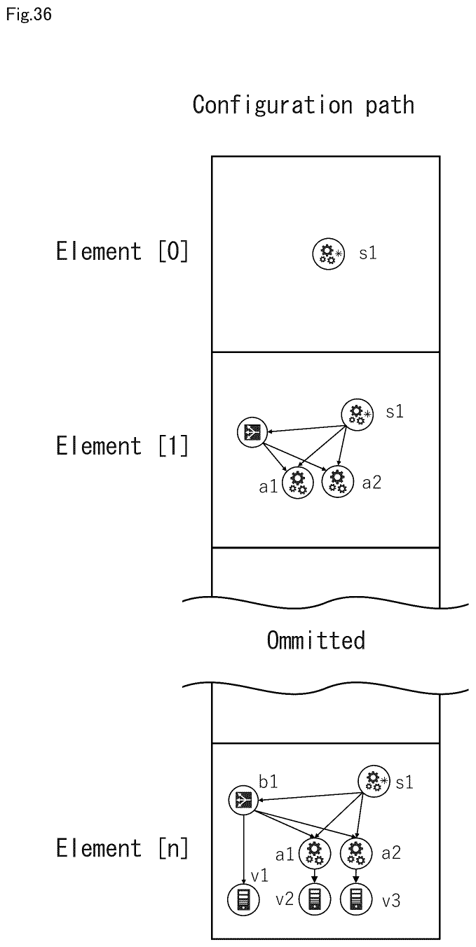

Here, an example of the configuration path CP1 is illustrated in FIG. 36. FIG. 36 illustrates a state in which the design illustrated in FIG. 30 branches due to the above-described operation in step S121, and illustrates an example in which the configuration path CP1 is generated in the order of (a)=> (b)=> . . . =>(f) as illustrated in FIG. 30.

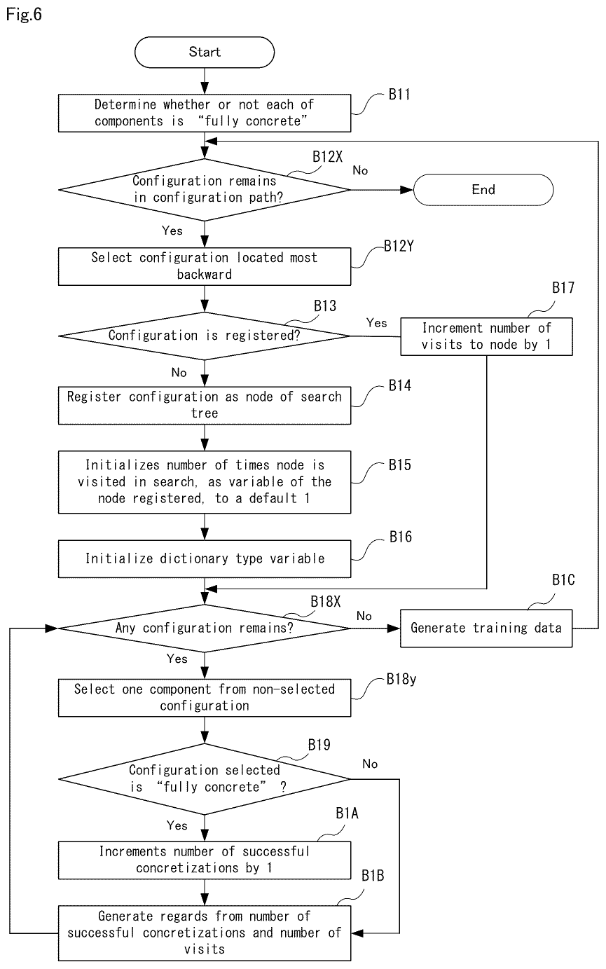

The operation of step S122 of generating training data is described in detail with reference to FIG. 6. The unit that performs the operation in step S122 is the reward generation unit 124 unless otherwise noted. Hereinafter, the current configuration at the point in time when step S121 is completed is referred to as the “ultimate configuration”.

First, the concretization success determination unit 123 determines whether or not each of the configuration elements contained in the ultimate configuration is “fully concrete” (step B11). The definition of a configuration element being “fully concrete” and determination method thereof will be described in detail later.

Then, the reward generation unit 124 determines whether or not any configuration that has not been selected in the previously executed step B12Y remains in the configuration path CP1 (step B12X). If the result of the determination in step B12X indicates that no configuration remains in the configuration path CP1, step S122 is ended.

On the other hand, if the result of the determination in step B12X indicates that any configuration remains in the configuration path CP1, the reward generation unit 124 executes the operations in steps B12Y to BIC, which will be described below, on the remaining configuration in order from the tail thereof.

Specifically, first, the reward generation unit 124 selects, from the configurations that have not been selected in the previously executed step B12Y, the configuration located most backward in the configuration path CP1 (step B12Y). Then, the reward generation unit 124 determines whether or not the configuration selected in step B12Y is registered as a node of a search tree T1 (step B13).

If the result of the determination in step B13 indicates that the configuration selected in step B12Y is not registered as a node of the search tree T1 (No in step B13), the reward generation unit 124 executes operations in steps B14 to B16, which will be described later.

First, the reward generation unit 124 registers the configuration under processing in step B12 as a node of the search tree T1 (step B14). The search tree T1 is a tree data structure that stores how much reward is obtained when components are concretized by the configuration.

Then, the reward generation unit 124 initializes the variable representing the number of times the node is visited in the search, as the variable of the node registered in step B14, to a default 1 (step B15). Hereinafter, the variable and content thereof are simply referred to as the “number of visits”.

Furthermore, the reward generation unit 124 initializes a dictionary type variable as the variable of the node (step B16). The dictionary type variable is a variable for which the number 20) of times each of the configuration elements contained in the configuration under processing in step B12 is “fully concrete” as a result of the design is stored for each configuration element. The dictionary type variable is also a dictionary type variable that has an identifier of a configuration element as a key and the number of times the configuration element is “fully concrete” as a value.

As a result of the initialization, all the values are set to 0. Hereinafter, the value that can be obtained by a dictionary type variable using the identifier of a configuration element as a key is referred to as the “number of successful concretizations” of the configuration element. Note here that a dictionary type variable is taken as an example, but a data structure of any type other than the dictionary type may be used as long as it is a data structure in which the number of times each of the configuration elements contained in the configuration under processing in step B12 is “fully concrete” as a result of the design can be stored for each configuration element. After step B16, step B18X is executed.

On the other hand, if the result of the determination in step B13 indicates that the configuration selected in step B12Y is registered as a node of the search tree T1 (Yes in step B13), the reward generation unit 124 increments the number of visits to the node by 1 (step B17). After step B16, step B18X is executed.

Then, the reward generation unit 124 determines whether or not in the configuration path CP1, any configuration that has not been selected in the previously executed step B18Y remains in the configuration selected in step B12Y (step B18X). If the result of the determination in step B18X indicates that any configuration remains, the reward generation unit 124 executes the 5 processing in steps B18Y to B1B, which will be described below.

First, the reward generation unit 124 selects one configuration element from the configuration elements contained in the configuration selected in step B12Y (step B18Y). Then, the reward generation unit 124 determines whether or not the configuration selected in step B18Y 10) is “fully concrete” in the ultimate configuration (step B19).

If the result of the determination in step B19 indicates that the configuration selected in step B18Y is “fully concrete” in the ultimate configuration (Yes in step B19), the reward generation unit 124 increments the number of successful concretizations of the node of the configuration selected in step B12Y by 1 (step BIA).

On the other hand, if the result of the determination in step B19 indicates that the configuration selected in step B18Y is not “fully concrete” in the ultimate configuration (No in step B19), the reward generation unit 124 executes the step BIB. That is, the reward generation unit 124 divides the value of the number of successful concretizations of the configuration element selected in step B18Y by the number of visits to the node of the configuration selected in step 20) B12Y, and regards the obtained quotient as a reward of the configuration element (step B1B). Then, the reward generation unit 124 executes step B18X again.

Also, if the result of the determination in step B18X indicates that no configuration element remains, the training data generation unit 125 generates, for each of the configuration elements contained in the configuration selected in step B12Y, training data including the configuration, the identifiers of the configuration elements, and the rewards of the configuration elements generated in step B1B, and adds the generated training data to the training data set (step BIC).

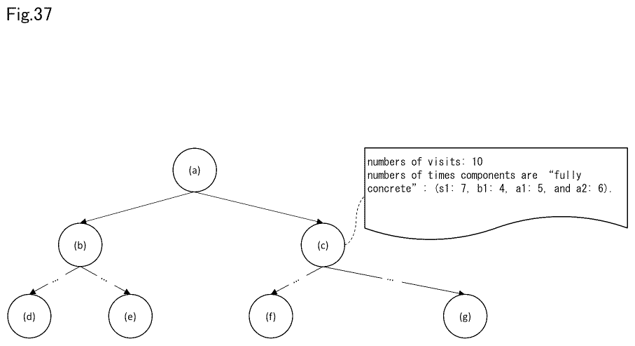

Here, an example of the search tree T1 is illustrated in FIG. 37. FIG. 37 illustrates an example of the configuration generated while the design illustrated in FIG. 30 branches, by the above-described operation in step S122. In FIG. 37, a character added to a node means the corresponding configuration represented by this node in FIG. 30. In the example of FIG. 37, to the node representing the configuration (c), information is added that indicates the number of visits (10), and the numbers of times the configuration elements included in the configuration (c) are “fully concrete” (s1: 7, b1: 4, a1: 5, and a2: 6). Although not illustrated in FIG. 37, the nodes (a) to (g) other than the configuration (c) similarly hold information indicating the number of visits and the number of times the configuration elements included in the configuration are “fully concrete”.

Before describing the operation in step B11 of determining whether or not a configuration element is “fully concrete” in detail, conditions for a configuration element to be “fully concrete” are schematically described. When a configuration element is “fully concrete”, this means that the configuration element including all other configuration elements required for this configuration element is concrete.

Here, the conditions for a configuration element to be “fully concrete” is to satisfy two conditions that will be described below. One condition is that the type of the configuration element is a concrete type. The other condition is that the type of the configuration element does not include an expected peripheral configuration, or the type of the configuration element includes an expected peripheral configuration and the expected peripheral configuration of the configuration element is satisfied.

Strict conditions for a configuration element to be “fully concrete” are defined recursively by two conditions listed below. One condition is that the configuration element is concrete. The other condition is that when the type of the configuration element includes an expected peripheral configuration and the expected peripheral configuration has been applied to the configuration element, all configuration elements appearing in the expected peripheral configuration are “fully concrete”.

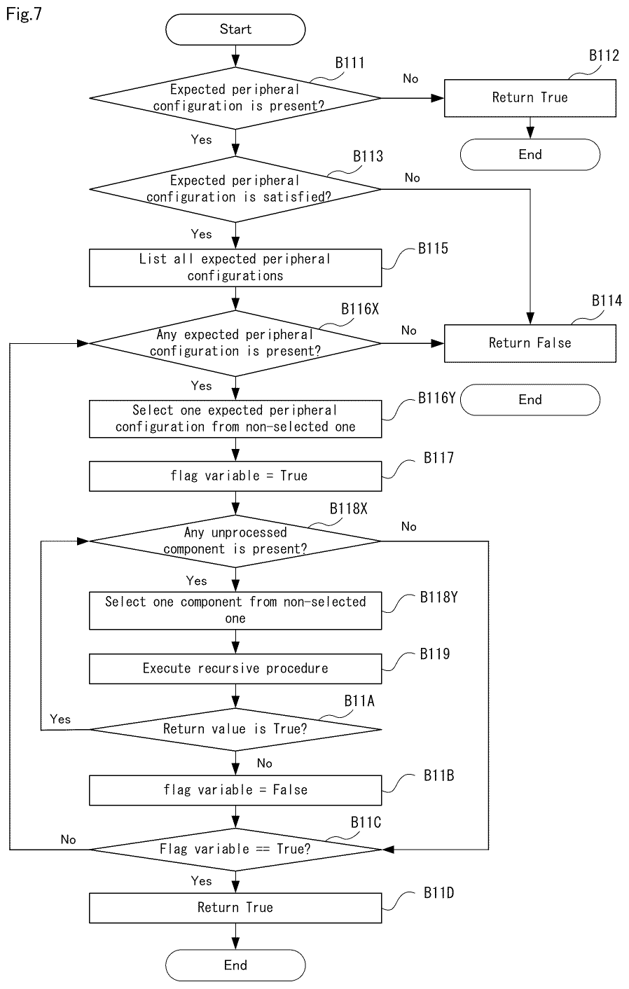

In view of them, the operation of step B11 of determining whether or not a configuration element is “fully concrete” is described in detail with reference to FIG. 7. The unit that performs the operation in step B11 is the concretization success determination unit 123 unless otherwise noted. Step B11 is defined as a recursive procedure with one configuration element and one configuration as arguments, which will be described below.

First, the concretization success determination unit 123 determines whether or not an expected peripheral configuration is present in the type of the configuration element of the argument (B111). If the result of the determination in step B111 indicates that no expected peripheral configuration is present in the type of the configuration element of the argument (No in step B111), the concretization success determination unit 123 returns True (step B112) and ends step B11.

On the other hand, if the result of the determination in step B111 indicates that an expected peripheral configuration is present in the type of the configuration element of the argument (Yes in step B111), the concretization success determination unit 123 determines whether or not an expected peripheral configuration of the configuration element of the argument is satisfied (step B113).

If the result of the determination in step B113 indicates that the expected peripheral configuration of the configuration element of the argument is not satisfied (No in step B113), the concretization success determination unit 123 returns False (step B114) and ends step B11.

On the other hand, if the result of the determination in step B113 indicates that the expected peripheral configuration of the configuration element of the argument is satisfied (Yes in step B113), the concretization success determination unit 123 lists all expected peripheral configurations of the configuration element of the argument present in the configuration of the 10) argument (step B115).

Then, the concretization success determination unit 123 determines whether or not any expected peripheral configuration that has not been selected in the previously executed step B116Y is still present (step B116X). If the result of the determination in step B116X indicates that any expected peripheral configuration that has not selected is still present, the concretization success determination unit 123 executes the operations in steps B116Y to B11D, which will be described below.

First, the concretization success determination unit 123 selects one expected peripheral configuration from the expected peripheral configurations listed in step B115 (step B116Y). Then, the concretization success determination unit 123 assigns True to a flag variable (step B117).

Furthermore, the concretization success determination unit 123 determines whether or not any unprocessed configuration element is present in the expected peripheral configuration selected in step B116Y (step B118X). If the result of the determination in step B118X indicates that no unprocessed configuration element is present in the expected peripheral configuration selected in step B116Y, the concretization success determination unit 123 executes step B11C.

On the other hand, if the result of the determination in step B118X indicates that any unprocessed configuration element is present in the expected peripheral configuration selected in step B116Y, the concretization success determination unit 123 executes the operations in steps B118Y to B11B, which will be described below.

First, the concretization success determination unit 123 selects one configuration element from the configuration elements contained in the expected peripheral configuration selected in step B116Y (step B118Y). Then, the concretization success determination unit 123 executes a recursive procedure in step B11 using the configuration element selected in step B118Y and the configuration of the argument in step B11 as arguments (step B119).

Then, the concretization success determination unit 123 determines whether or not the return value in step B119 is True (step B11A). If the result of the determination in step B11A indicates that the return value in step B119 is True (Yes in step B11A), the concretization success determination unit 123 executes the step B118X again.

On the other hand, if the result of the determination in step B11A indicates that the return value is False (No in step B11A), the concretization success determination unit 123 assigns False to the flag variable (step B11B).

Then, after the execution of step B11B or if the result in step B118X is No, the concretization success determination unit 123 determines whether or not the content of the flag variable is True (step B11C). If the result of the determination in step B11C indicates that the 10) content of the flag variable is True (Yes in step B11C), the concretization success determination unit 123 returns True (step B11D) and ends the operation in step B11.

On the other hand, if the result of the determination in step B11C indicates that the content of the flag variable is False (No in step B11C), the concretization success determination unit 123 executes the step B116X again.

Also, if the result of the determination in step B116X indicates that there is not any expected peripheral configuration that has not selected, since it means that all the expected peripheral configurations have been completely processed, the concretization success determination unit 123 returns False (step B114) and ends the operation in step B11.

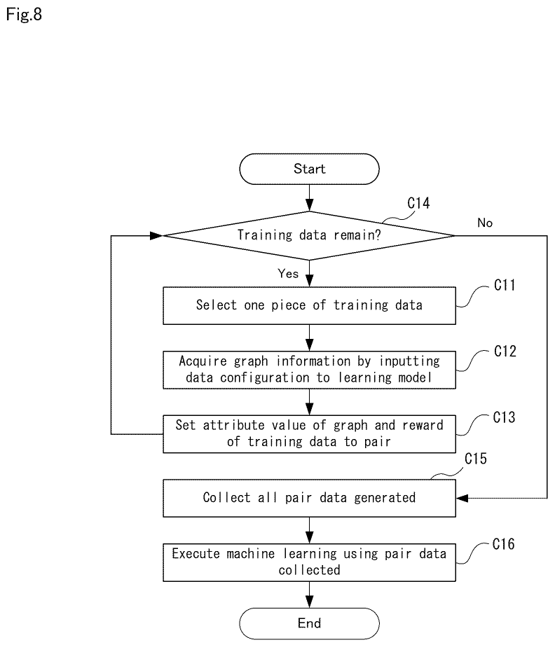

The operation of step S124 of performing learning based on the training data is described in detail with reference to FIG. 8. The unit that performs the operation in step S124 is the machine learning unit 126 unless otherwise noted. The learning model of the configuration element evaluation unit 111 is a Graph Neural Network (GNN) that receives, as inputs, nodes and edges in a graph and graph information in which the graph itself has an attribute value and outputs graph information of the same format.

First, the machine learning unit 126 selects, from the training data set stored in step S122, one piece of training data LD1 (step C11). Then, the machine learning unit 126 inputs graph information indicating a configuration contained in the training data LD1 to the learning model of the configuration element evaluation unit 111, and regards graph information output as a consequence from the learning model of the configuration element evaluation unit 111 as OG1 (step C12).

Then, the machine learning unit 126 regards, among configuration elements contained in OG1, a set of an attribute value PV1 of the configuration element having the same identifier as the identifier of the configuration element contained in the training data LD1 and a reward contained in the training data LD1, as VP1 (step C13).

Then, the machine learning unit 126 determines whether or not all the pieces of training data have been selected from the training data set (step C14). If the result of the determination in step C14 indicates that all the pieces of training data have not been selected from the training data set (Yes in step C14), the machine learning unit 126 executes steps C11 to C13 again.

On the other hand, if the result of the determination in step C14 indicates that all the pieces of training data have been selected from the training data set (No in step C14), the machine learning unit 126 generates VP1 for all the pieces of data contained in the training data and regards the collection of the VP1 as VPS1 (step C15).

Furthermore, the machine learning unit 126 executes machine learning on the learning model of the configuration element evaluation unit 111 so that for each pair included in the VPS1, a loss function is defined for an attribute value and a mean squared error of fixed rewards, and the loss function is minimized (step C16).

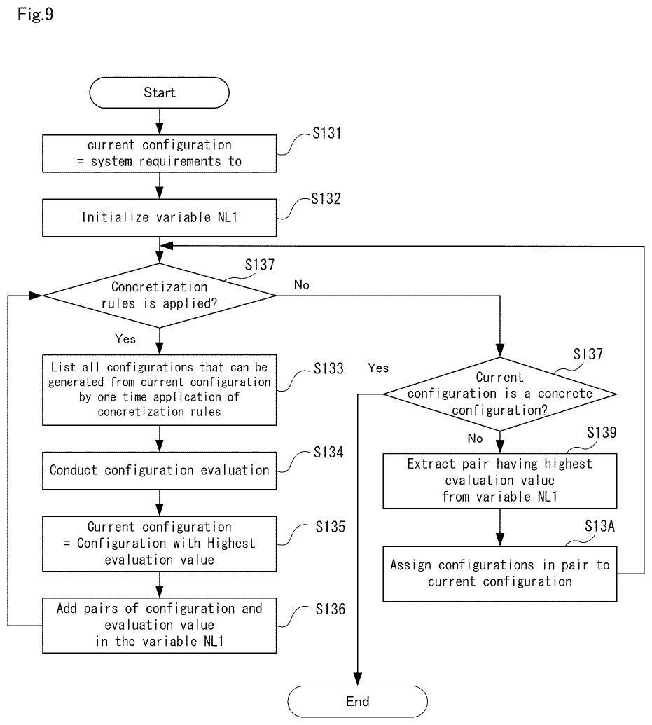

The operation of step S13 of performing design trial in the process of learning is described in detail with reference to FIG. 9. The unit that performs the operation in step S13 is the design trial unit 122 unless otherwise noted.

First, the design trial unit 122 assigns the system requirements R1 to the variable representing the current configuration (step S131). Hereinafter, content assigned to the variable representing the current configuration is expressed simply by “current configuration”. Then, the design trial unit 122 initializes a variable NL1, which stores a configuration candidate to be next assigned to the variable representing the current configuration, as an empty list (step S132).

Then, the design trial unit 122 determines whether or not the concretization rules can be applied to the current configuration (step S137). If the result of the determination in step S137 indicates that the concretization rules cannot be applied to the current configuration, later-described step S138 is executed.

On the other hand, if the result of the determination in step S137 indicates that the concretization rules can be applied to the current configuration, the design trial unit 122 lists all the configurations that can be generated from the current configuration by one time application of concretization rules (step S133).

Furthermore, the design trial unit 122 inputs the configurations listed in step S133 to the configuration comprehensive evaluation unit 112, and conducts configuration evaluation (step S134). The configuration evaluation operation T1 will be described in detail later. Then, the design trial unit 122 assigns, among the configurations obtained by the processing in step S134, the configuration with the highest evaluation value to the variable representing the current configuration (step S135).

Then, among the configurations listed in step S133, pairs of a configuration other than the configurations assigned to the variable representing the current configuration in step S135, and the evaluation value of this configuration obtained in step S134 are added to the list stored in the variable NL1 (step S136).

After the execution of step S136, the design trial unit 122 executes step S137 again. If the result of the determination in step S137 indicates that the concretization rules can be applied to the current configuration, the design trial unit 122 executes step S133 again.

On the other hand, if the result of the determination in step S137 indicates that the concretization rules cannot be applied to the current configuration, the design trial unit 122 determines whether or not the current configuration is a concrete configuration (step S138). If the result of the determination in step S138 indicates that the current configuration is a concrete configuration (Yes in step S138), the operation in step S13 is ended.

On the other hand, if the result of the determination in step S138 indicates that the current configuration is not a concrete configuration (No in step S138), the design trial unit 122 extracts, from the list stored in the variable NL1, the pair having the highest evaluation value (step S139). Then, the design trial unit 122 assigns the configuration contained in the pair extracted in step S139 to the variable representing the current configuration (step S13A). Then, the design trial unit 122 moves to step S137 again.

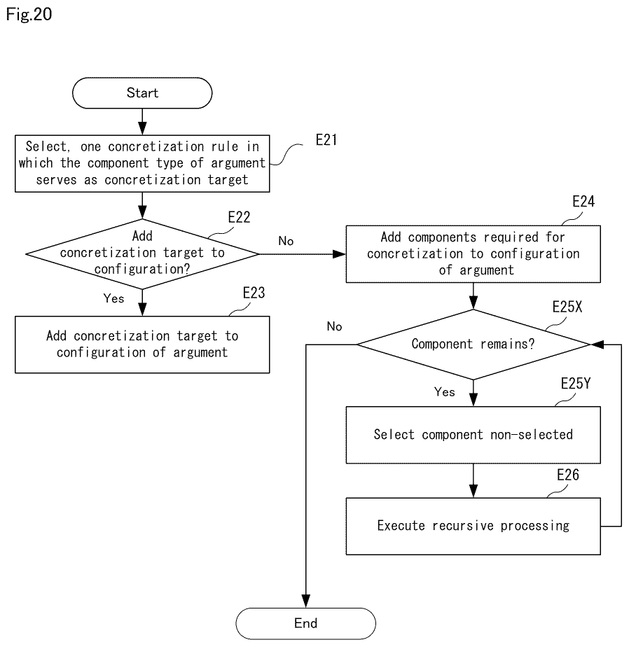

The configuration evaluation operation T1 is described in detail with reference to FIG. 20) 10. The unit that performs the configuration evaluation operation T1 is the configuration comprehensive evaluation unit 112 unless otherwise noted.

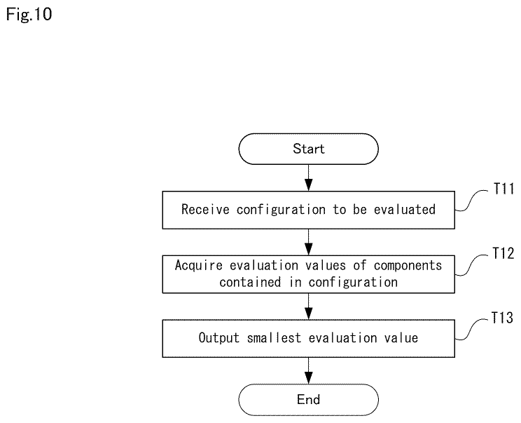

First, as illustrated in FIG. 10, the configuration comprehensive evaluation unit 112 receives a configuration to be evaluated, as an input (step T11). Then, the configuration to be evaluated that was received as an input in step T11 is input to the configuration element evaluation unit 111, and evaluation values of the configuration elements contained in the input configuration are obtained (step T12).

Furthermore, the configuration comprehensive evaluation unit 112 regards, among the evaluation values of the configuration elements obtained in step T12, the smallest evaluation value as the evaluation value of the configuration to be evaluated (step T13). In step T13, as described above, an evaluation value expresses the probability as to whether the corresponding configuration element can be fully concretized. Note that the method of determining an evaluation value is not particularly limited to the above-described step T13. As the evaluation value of the configuration to be evaluated, the average of the evaluation values of the configuration elements may be used or the maximum of the evaluation values of the configuration elements may be used.

### [Description of Effects]

In Example Embodiment 1, instead of the probability of success of the design of the overall system configuration, the probability of success of the concretization of each configuration element is learned. That is, a reward is generated based on success of the concretization of each configuration element, and an evaluation that represents the probability that the concretization will be successfully completed for each configuration element based on the reward is learned.

This enables learning in units of configuration elements, thereby solving the problem that when some of the configurations are changed, learned content cannot be applied due to the impact of the change being unknown. This enables application in units of configuration elements even when the overall configuration is changed. This also solve the problem that the amount of data and time required for learning increase with the size of the system configuration and is not scalable, thereby improving the learning efficiency of automated design of the ICT system.

### [Program]

In Example Embodiment 1, the program need only be a program that causes a computer to execute the steps illustrated in FIGS. 3 to 10. By installing this program in the computer and executing the installed program, it is possible to realize the system configuration evaluation apparatus 1 and the system configuration evaluation method. In this case, a processor of the computer functions as the configuration evaluation unit 11 and the configuration element learning unit 12 and executes the processing. Examples of the computer include, in addition to a general-purpose PC, a smartphone and a tablet-type terminal device.

Also, the program may be executed by a computer system constituted by a plurality of computers. In this case, for example, one or more computers may function as the configuration evaluation unit 11 or the configuration element learning unit 12.

### Example Embodiment 2

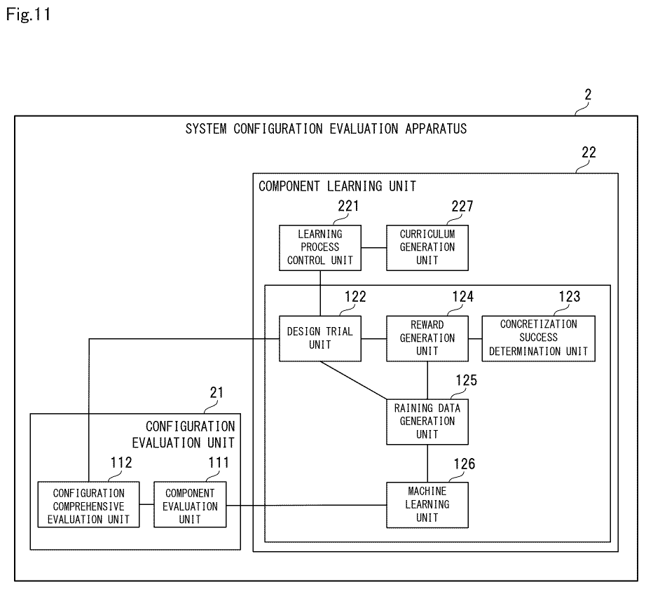

The following will describe a system configuration evaluation apparatus, a system configuration evaluation method, and a program according to Example Embodiment 2 with reference to FIGS. 11 to 22.

In Example Embodiment 2, curriculum learning is executed. Curriculum learning is an efficient learning method in which a large problem to be learned is divided into smaller problems, and the problems are learned in an appropriate sequence. In Example Embodiment 2, a large problem of designing the entire configuration is divided into smaller problems of concretizing configuration elements contained in the configuration, and the smaller problems are learned in an appropriate sequence. In the following, the same descriptions as those in Example Embodiment 1 are omitted as appropriate.

### [Apparatus Configuration]

First, a configuration of the system configuration evaluation apparatus according to Example Embodiment 2 is described with reference to FIG. 11. FIG. 11 is a configuration diagram illustrating an example of a configuration of the system configuration evaluation apparatus.

As illustrated in FIG. 11, the system configuration evaluation apparatus 2 includes a configuration evaluation unit 21 and a configuration element learning unit 22. Furthermore, the configuration evaluation unit 21 includes the configuration element evaluation unit 111 and the configuration comprehensive evaluation unit 112. The configuration element learning unit 22 includes a learning process control unit 221, the design trial unit 122, the concretization success 10) determination unit 123, the reward generation unit 124, the training data generation unit 125, the machine learning unit 126, and a curriculum generation unit 227. These units operate substantially as follows.

The configuration element evaluation unit 111, the configuration comprehensive evaluation unit 112, the design trial unit 122, the concretization success determination unit 123, the reward generation unit 124, the training data generation unit 125, and the machine learning unit 126, and overviews of the operations thereof are the same as the operations of the corresponding units described in Example Embodiment 1.

However, in Example Embodiment 2, as described above, the configuration element learning unit 22 includes the curriculum generation unit 227, and Example Embodiment 2 differs 20) from Example Embodiment 1 in this respect. Accordingly, the operation of the learning process control unit 221 is also different.

The curriculum generation unit 227 generates, based on a dependence relationship representing a relationship between a specific configuration element and another configuration element required to concretize the specific configuration element, a curriculum in a manner such that learning is executed in the order of configuration elements with no dependence relationship and configuration elements with a dependence relationship for which learning is completed.

The learning process control unit 221 controls the execution of learning processes in accordance with the curriculum generated by the curriculum generation unit to execute machine learning on the learning model. In this case, there are two major types of learning processes, namely, initial learning and re-learning. Details thereof will be described later.

### [Apparatus Operations]

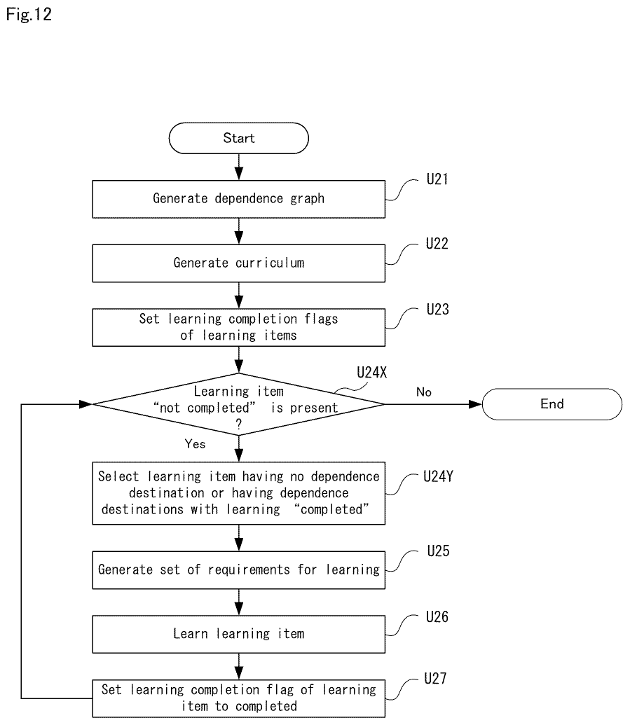

The following will describe an example of the operation of the system configuration evaluation apparatus 2 according to Example Embodiment 2 with reference to FIGS. 12 to 22. In the following description, FIG. 11 is referenced as appropriate. Also, in Example Embodiment 2, a system configuration evaluation method is executed by operating the system configuration evaluation apparatus 2. Accordingly, in Example embodiment 2, description of the system configuration evaluation method is replaced with the following description on the operation of the system configuration evaluation apparatus.

In Example Embodiment 2, the operations are broadly divided into three operations. The three operations include an operation of initial learning of configuration element evaluation, an operation of re-learning of configuration element evaluation, and an operation of configuration evaluation. In the operation of initial learning of configuration element evaluation, training of a learning model for which no training with respect to evaluation of an ICT system in units of configuration elements was performed in the past is executed in order to evaluate the system configuration of the ICT system. In the re-learning of configuration evaluation, training of the learning model trained in the past with respect to evaluation of the ICT system in units of configuration elements is executed. In the operation of configuration evaluation, the trained learning model is used to execute evaluation of the system configuration of the ICT system. The following will describe the operations.

An initial learning operation U2 of configuration evaluation by the system configuration evaluation apparatus 2 will be described in detail with reference to FIG. 12.

First, as illustrated in FIG. 12, the curriculum generation unit 227 generates a dependence graph (step U21). Then, the curriculum generation unit 227 generates a curriculum (step U22). A curriculum has a graph structure and nodes in the curriculum are referred to as “learning items”.

Then, the curriculum generation unit 227 sets learning completion flags of the learning items in the curriculum to not completed (step U23). The curriculum generation unit 227 then determines whether or not the curriculum includes any learning item having a learning completion flag set to “not completed” (step U24X). If the result of the determination in step U24X indicates that the curriculum does not include any learning item having a learning completion flag set to “not completed”, the operation U2 is ended.

On the other hand, if the result of the determination in step U24X indicates that the curriculum includes any learning item having a learning completion flag set to “not completed”, the curriculum generation unit 227 performs operations in steps U25 to U27, which will be described later.

First, the learning process control unit 221 selects, from the curriculum, one learning item that has no dependence destination or has dependence destinations all having a learning completion flag set to “completed” (step U24Y). Then, the curriculum generation unit 227 generates a set of requirements for learning the learning item selected in step U24Y (step U25).

Furthermore, the configuration element learning unit 22 learns the learning item selected in step U24Y using the set of requirements generated in step U25 (step U26). Then, the learning process control unit 221 sets the learning completion flag of the learning item selected in step U24Y to completed (step U27). Then, the learning process control unit 221 executes step U24X again.

Before describing the operation U21 of generating a dependence graph, the following will describe a dependence graph. A dependence graph is information on a graph structure representing a dependence relationship of configuration element types. A configuration element type is denoted by a node, and a dependence relationship between configuration element types is denoted by a 10) directed edge. A dependence relationship in a dependency graph is a relationship that represents the types of other configuration elements required for a configuration element of a certain type to function properly in a system configuration.

For example, if information on a presupposition configuration or essential configuration, which is an expected peripheral configuration of a configuration element type ET_X, includes a configuration element type ET_Y, the configuration element of the type ET_Y is required for the configuration element of the type ET_X to function. At this time, there is a dependence relationship between the type ET_X and the type ET_Y, and it is expressed that the ET_X depends on the type ET_Y.

A directed edge is drawn from the node of a configuration element type to the node of another configuration element type on which that configuration element type depends. In the foregoing example, a directed edge is drawn from a node of the type ET_X to a node of the type ET_Y.

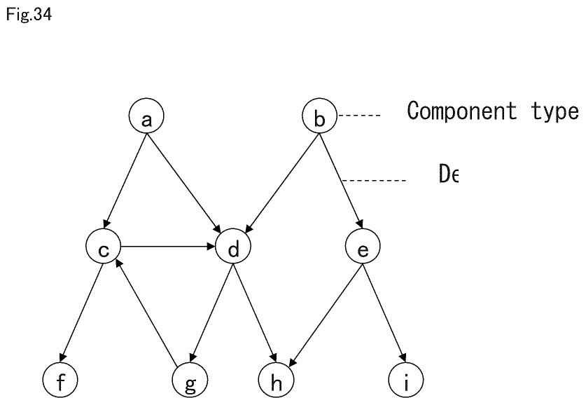

FIG. 34 illustrates an example of a dependence graph. In FIG. 34, a character added to a node means the name of the configuration element type represented by this node. Descriptions of all configuration element types included in FIG. 34 are omitted, but when, for example, a configuration element type c is focused, the configuration element type c depends on configuration element types d and f, and configuration element types a and g depend on the configuration element type c.

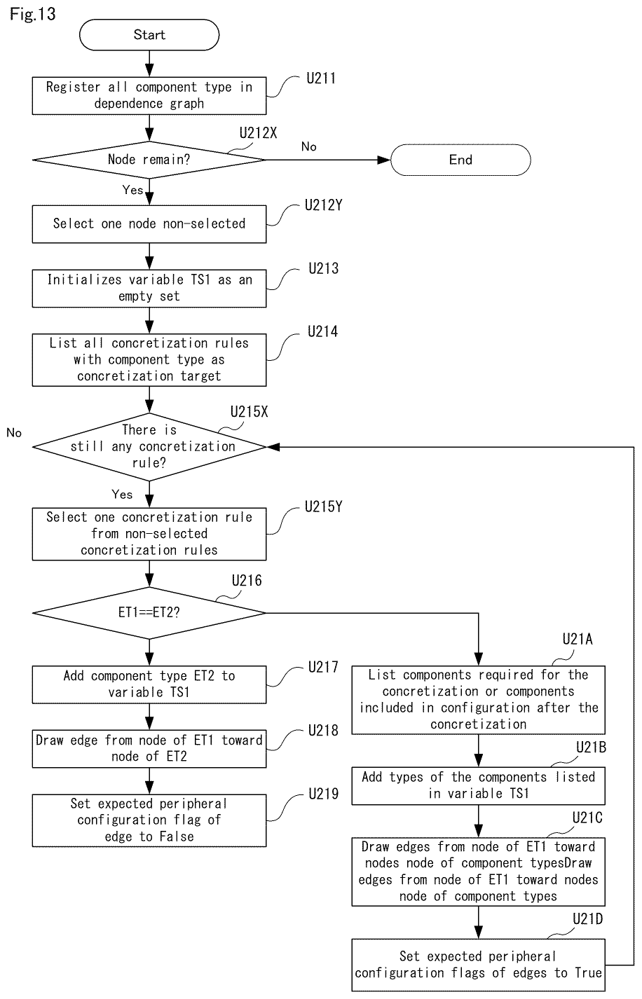

Step U21 of generating a dependence graph is described in detail with reference to FIG. 13. The unit that performs the operation in step U21 is the curriculum generation unit 227 unless otherwise noted.

First, as illustrated in FIG. 13, the curriculum generation unit 227 registers, for all configuration element types defined in configuration element type definition information, the nodes representing the respective types in the dependence graph (step U211).

Then, the curriculum generation unit 227 determines whether or not in the nodes registered in the dependence graph, there is any node that has not yet been selected in the later-described step U212Y (step U212X). If the result of the determination in step U212X indicates that there is no node that has not yet been selected, step U21 is ended. On the other hand, if the result of the determination in step U212X indicates that there is any node that has not yet selected, the curriculum generation unit 227 executes the operations in steps U212Y to U219, which will be described below.

First, the curriculum generation unit 227 selects, from all the nodes registered in the dependence graph, one node that has not yet been selected (step U212Y). Then, the curriculum 10) generation unit 227 causes the node selected in step U212Y to have, as a variable, a variable TS1 for storing a set of configuration element types on which the configuration element type ET1 represented by the node selected in step U212Y depends, and initializes the variable TS1 as an empty set (step U213).

Furthermore, the curriculum generation unit 227 lists, from the concretization rules defined in the concretization rules definition information, all concretization rules with the configuration element type ET1 as a concretization target (step U214). Then, the curriculum generation unit 227 determines whether or not there is still any concretization rule (step U215X).

If the result of the determination in step U215X indicates that there is no concretization rule, the curriculum generation unit 227 executes step U212X again. On the other hand, if the result of the determination in step U215X indicates that there is still any concretization rule, the curriculum generation unit 227 executes the operations in steps U215Y to U219, which will be described below, on the concretization rules listed in step U214.

First, the curriculum generation unit 227 selects one concretization rule from the concretization rules listed in step U214 (step U215Y). Then, the curriculum generation unit 227 determines whether or not, among configuration elements contained in the configuration after the concretization of the concretization rule selected in step U215Y, the configuration element type ET2 of the configuration element whose identifier is equal to that of the configuration element for which the concretization rules selected in step U215Y is to be concretized is identical to the configuration element type ET1 (step U216).

If the result of the determination in step U216 indicates that the configuration element type ET2 is not identical to the configuration element type ET1 (No in step U216), the curriculum generation unit 227 adds the configuration element type ET2 as an element of the set stored in the variable TS1 (step U217).

Then, the curriculum generation unit 227 draws an edge from the node selected in step U212Y toward the node representing the configuration element type ET2 registered in the dependence graph (step U218). Furthermore, the curriculum generation unit 227 sets an expected peripheral configuration flag of the edge drawn in step U218 to False (step U219). Then, the curriculum generation unit 227 executes step U21A. The expected peripheral configuration flag is a flag indicating whether or not the edge represents the dependence relationship based on the expected peripheral configuration.

Also, if the result of the determination in step U216 indicates that the configuration element type ET2 is identical to the configuration element type ET1 (Yes in step U216) or after step U219 has been executed, the curriculum generation unit 227 executes step U21A.

Specifically, the curriculum generation unit 227 lists all configuration elements of the concretization rule selected in step U215Y that are required for the concretization or that are included in the configuration after the concretization (step U21A). Furthermore, the curriculum generation unit 227 adds the types of the configuration elements listed in step U21A as elements of the set stored in the variable TS1 (step U21B).

Then, with respect to the configuration element types added as elements of the set stored in the variable TS1 in step U21B, the curriculum generation unit 227 draws edges from the node selected in step U212Y toward the nodes representing the configuration element types registered in the dependence graph (step U21C). Then, the curriculum generation unit 227 sets expected peripheral configuration flags of the edges drawn in step U21C to True (step U21D).

Before describing the operation U22 of generating a curriculum, the following will describe a curriculum. A curriculum refers to information on a graph representing a partial order relation of learnings conducted in curriculum learning. In the graph, a learning item is denoted by a node, and a dependence relationship between learning items is denoted by a directed edge.

A learning item refers to individual learning that is conducted in curriculum learning, and in the example embodiment, the learning item holds at least information on the configuration element type to be learned. A dependence relationship in the curriculum refers to a relationship that represents another learning item that needs to be learned in advance in order to learn a certain learning item.

For example, it is assumed that a learning target in a learning item LT_X is a configuration element type ET_X, a learning target in a learning item LT_Y, which is different from the learning item LT_X, is a configuration element type ET_Y, and the configuration element type ET_X depends on the configuration element type ET_Y. In this case, in the design using the configuration element type ET_X, there is a possibility that the configuration element type ET_Y appears, and thus the learning item LT_Y needs to be learned before the learning item LT_X. At this time, there is a dependence relationship between the learning items LT_X and LT_Y, and it is expressed that the learning item LT_X depends on the learning item LT_Y.

A directed edge is drawn from the node of a learning item to the node of another learning item on which this learning item depends. In the foregoing example, a directed edge is drawn from the node of the learning item LT_X to the node of the learning item LT_Y. Note that as is clear from the above description, a dependence relationship between learning items is only established if there is a dependence relationship between the configuration element types of the learning items that are learning targets. Therefore, a dependence graph and a curriculum graph are basically of the same type.

However, if a cycle (closed circuit formed by directed edges in the graph) is once formed in the curriculum, it would be impossible to determine the order in which the learning items included in the cycle are learned. Accordingly, the curriculum is a graph in which a cycle is deleted from the dependence graph, that is, a graph in which some of edges included in each cycle are removed.

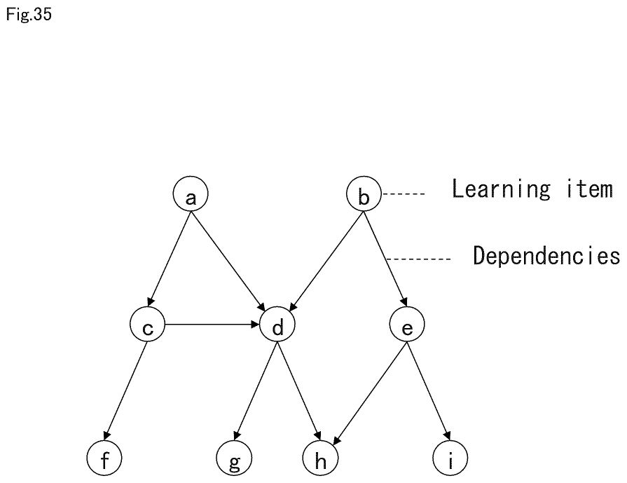

In view of such circumstance, the curriculum is generated based on the dependency graph. An example of a curriculum generated based on the dependence graph in FIG. 34 is illustrated in FIG. 35. A character added to each node means the name of the configuration element type to be learned for the learning item represented by this node. Descriptions of all configuration element types included in FIG. 35 are omitted, but when, for example, a configuration element type c is focused, the configuration element type c depends on configuration element types d and f, and the learning item a depends on the configuration element type c. As illustrated in FIG. 35, the directed edge from the node g to the node c included in the dependence graph in FIG. 34 is removed, and the cycle of node c=>d=>g=>c included in the dependence graph in FIG. 34 is deleted.

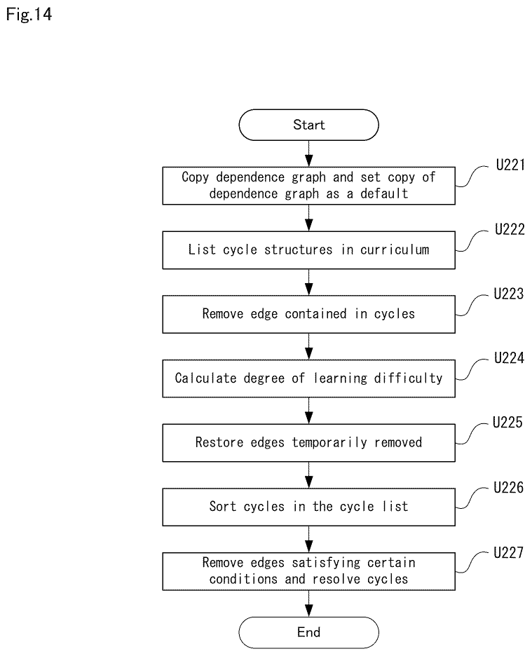

The operation of step U22 of generating a curriculum is described in detail with reference to FIG. 14. The unit that performs the operation in step U22 is the curriculum generation unit 227 unless otherwise noted.

First, as illustrated in FIG. 14, the curriculum generation unit 227 copies the dependence graph generated in step U21 and sets the copy of the dependence graph as a default of the curriculum (step U221). A curriculum has a graph structure and nodes in the curriculum are referred to as “learning items”.

Then, the curriculum generation unit 227 detects and lists cycle structures (hereinafter, simply denoted as “cycles”) of the graph included in the curriculum (step U222). Hereinafter, listed cycles are denoted as “cycle list”.

Furthermore, the curriculum generation unit 227 temporarily removes, from the curriculum, an edge contained in each of the cycles detected in step U222 (step U223). Then, the curriculum generation unit 227 calculates, for each of the learning items in the curriculum, the degree of learning difficulty of the learning item (step U224).

Then, the curriculum generation unit 227 restores the edges temporarily removed from the curriculum in step U223 in the curriculum (step U225). Furthermore, the curriculum generation unit 227 sorts the cycles in the cycle list obtained in step U222 in a specific order (step U226).

Also, for each cycle in the cycle list sorted in step U226, the curriculum generation unit 227 removes edges that satisfy certain conditions included in the cycle and resolves the cycles 10) (step U227).

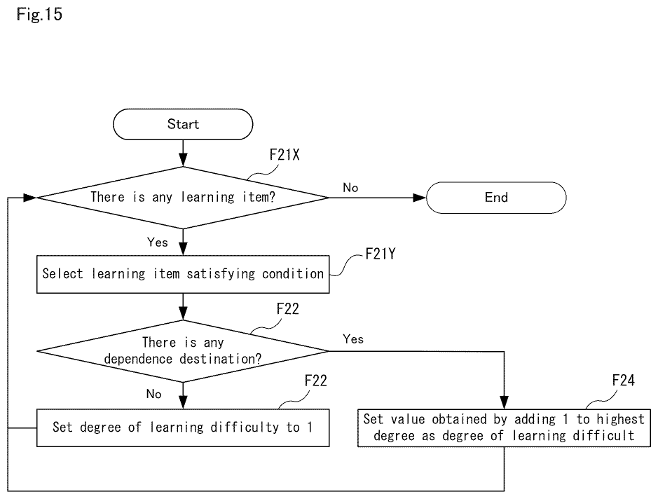

The operation of step U224 of calculating the degree of learning difficulty is described in detail with reference to FIG. 15. The unit that performs the operation in step U224 is the curriculum generation unit 227 unless otherwise noted.

First, as illustrated in FIG. 15, the curriculum generation unit 227 determines whether or not there is any learning item to be processed (step F21X). If the result of the determination in step F21X indicates that there is no learning item, step U224 is ended. On the other hand, if the result of the determination in step F21X indicates that there is any learning item, the curriculum generation unit 227 performs operations in steps F21Y to F24, which will be described later.

First, the curriculum generation unit 227 selects one learning item from the curriculum that has no dependence destination or has dependence destinations for which the degrees of learning difficulty have been all calculated (step F21Y). Then, the curriculum generation unit 227 determines whether or not there is any dependence destination of the learning item selected in step F21Y (step F22).

If the result of the determination in step F22 indicates that there is no dependence destination of the learning item selected in step F21Y (No in step F22), the curriculum generation unit 227 sets the degree of learning difficulty of the learning item to 1 (step F23). Then, the curriculum generation unit 227 executes step F21X again.

On the other hand, if the result of the determination in step F22 indicates that there is any dependence destination of the learning item selected in step F21Y (Yes in step F22), the curriculum generation unit 227 sets the value obtained by adding 1 to the highest degree, among the learning difficulties of the learning items of the dependence destination, as the degree of learning difficulty of the learning item selected in step F21Y (step F24).

The following will describe the cycle sorting method executed in step U226 illustrated in FIG. 14 in detail. The unit that performs the operation in step U226 is the curriculum generation unit 227 unless otherwise noted. First, the curriculum generation unit 227 counts the number of times CC that each edge is included in a cycle, sets the largest CC value of the edge included in each cycle as a value SV1 for use in sorting the cycles, and sorts the cycles in descending order of the values SV1 (sort condition SC1).

If the values SV1 for use in sorting obtained under sort condition SC1 are the same, the curriculum generation unit 227 sets the value of the edge with the largest CC value among the edges contained in each cycle, as a value SV2 for use in sorting the cycles. If cycles have the same SV1 value, the cycles are sorted in descending order of the values SV2 (sort condition SC2).

If the values SV2 for use in sorting obtained under the sort condition SC2 are the same, the curriculum generation unit 227 sorts the values with a suitable method for performing determination in a unique order (sort condition SC3). For example, a character string in which the names of configuration element types that are learning objects of training items in cycles are arranged and connected in a cycle order such that the first one in alphabetical order is placed at the head is set as a character string SV3, and the cycle may be sorted so that SV3 is in alphabetical order.

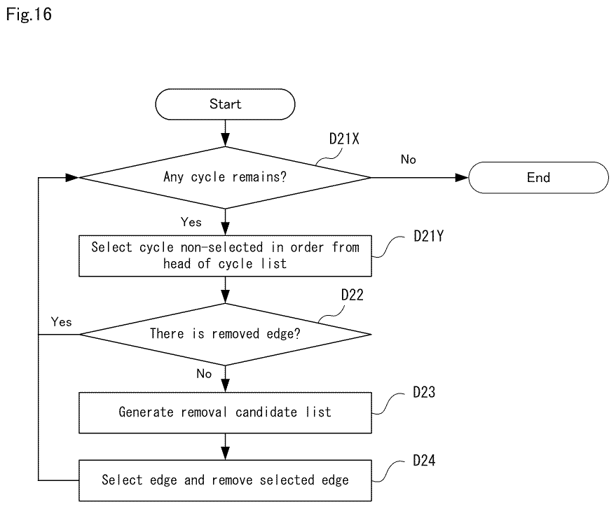

The operation of step U227 of removing an edge and resolving a cycle is described in detail with reference to FIG. 16. The unit that performs the operation in step U227 is the curriculum generation unit 227 unless otherwise noted.

First, as illustrated in FIG. 16, the curriculum generation unit 227 determines whether or not any unprocessed cycle remains in the cycle list sorted in step U226 (step D21X). If the result of the determination in step D21X indicates that no unprocessed cycle remains in the cycle list, step U227 is ended. On the other hand, if any unprocessed cycle remains in the cycle list sorted in step U226, the curriculum generation unit 227 performs operations in steps D21Y to D24, which will be described later.

First, the curriculum generation unit 227 selects one cycle that is not selected in step D21Y in order from the head of the cycle list sorted in step U226 (step D21Y). Then, the curriculum generation unit 227 determines whether or not the cycle selected in step D21Y includes a removed edge (step D22).

If the result of the determination in step D22 indicates that the cycle selected in step D21Y includes at least one removed edge (Yes in step D22), the curriculum generation unit 227 executes step D21X again. With this, the procedure moves to the next loop processing.

On the other hand, if the result of the determination in step D22 indicates that the cycle selected in step D21Y does not include any removed edge (No in step D22), the curriculum generation unit 227 generates a removal candidate list for edges included in the cycle (step D23).

Furthermore, the curriculum generation unit 227 selects one edge from the removal candidate list generated in step D23 using a suitable method, and removes the selected edge (step D24).

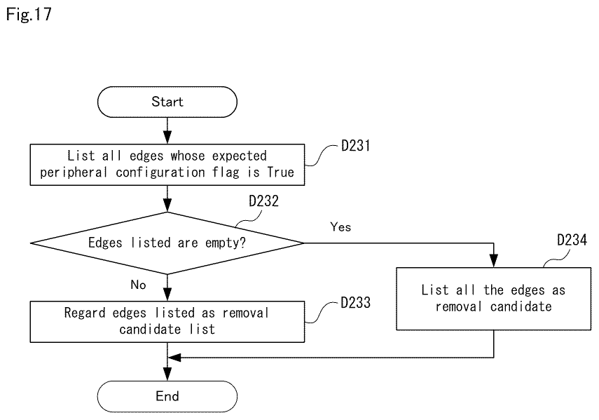

The operation of step D23 of generating a removal candidate list for edges included in the cycle is described in detail with reference to FIG. 17. The unit that performs the operation in step D23 is the curriculum generation unit 227 unless otherwise noted. The removal candidate list refers to variables of the list type data structure for storing edges to serve as candidates to be removed for resolving the cycle.

First, as illustrated in FIG. 17, the curriculum generation unit 227 lists all edges whose 10) expected peripheral configuration flag is True, among the edges included in the cycle (step D231).

Then, the curriculum generation unit 227 determines whether or not the edges listed in step D231 are empty (step D232).

If the result of the determination in step D232 indicates that the edges listed in step D231 are not empty (No in step D232), the curriculum generation unit 227 regards the list in which the edges listed in step D231 are stored as a removal candidate list (step D233).

On the other hand, if the result of the determination in step D232 indicates that the edges listed in step D231 are empty (Yes in step D232), the curriculum generation unit 227 regards a removal candidate list in which all the edges included in the cycle are stored as the removal candidate list (step D234).

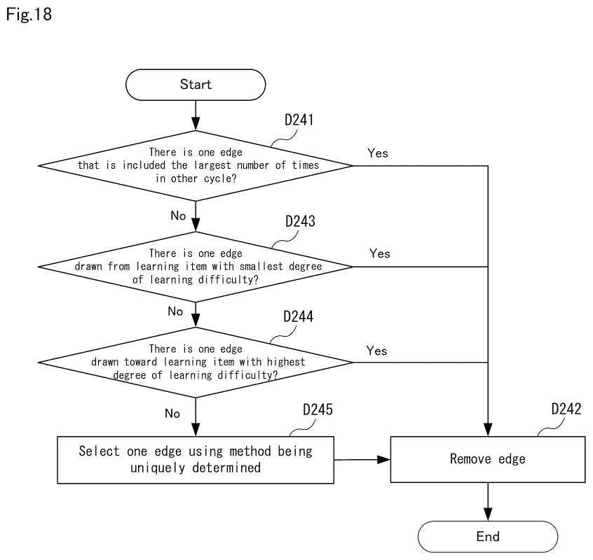

The operation of step D24 of removing one edge from the removal candidate list is described in detail with reference to FIG. 18. The unit that performs the operation in step D24 is the curriculum generation unit 227 unless otherwise noted.

First, as illustrated in FIG. 18, the curriculum generation unit 227 determines whether or not, among the edges included in the removal candidate list, there is one edge that is included the largest number of times in a cycle other than the cycle selected in step D21Y (step D241).

If the result of the determination in step D24 indicates that there is one such edge (Yes in step D241), the curriculum generation unit 227 removes the edge (step D242) and ends the operation in step D24.

If the result of the determination in step D24 indicates that the number of such edges is not one (No in step D241), the curriculum generation unit 227 determines whether or not, among edges with the largest number of times they are included in a cycle other than the cycle selected in step D21Y, there is one edge drawn from the learning item with the smallest degree of learning difficulty (step D243).

If the result of the determination in step D243 indicates that there is one such edge (Yes in step D243), the curriculum generation unit 227 removes the edge (step D242) and ends the operation in step D24.

On the other hand, if the result of the determination in step D243 indicates that the number of such edges is not one (No in step D243), the curriculum generation unit 227 determines whether or not, among edges with the largest number of times they are included in a cycle other than the cycle selected in step D21Y, there is one edge drawn toward the learning item with the highest degree of learning difficulty (step D244).

If the result of the determination in step D244 indicates that there is one such edge (Yes in step D244), the curriculum generation unit 227 removes the edge (step D242) and ends the 10) operation in step D24.

On the other hand, if the result of the determination in step D244 indicates that the number of such edges is not one (No in step D244), the curriculum generation unit 227 selects one edge from the edges with the largest number of times they are included in a cycle other than the cycle selected in step D21Y using a suitable method that can be uniquely determined (step D245), removes the selected edge (step D242), and ends the operation of step D24. Note that an example of the selection criterion in step D245 is that an edge drawn from a learning item whose learning target is the configuration element type with the earliest name in alphabetical order is selected.

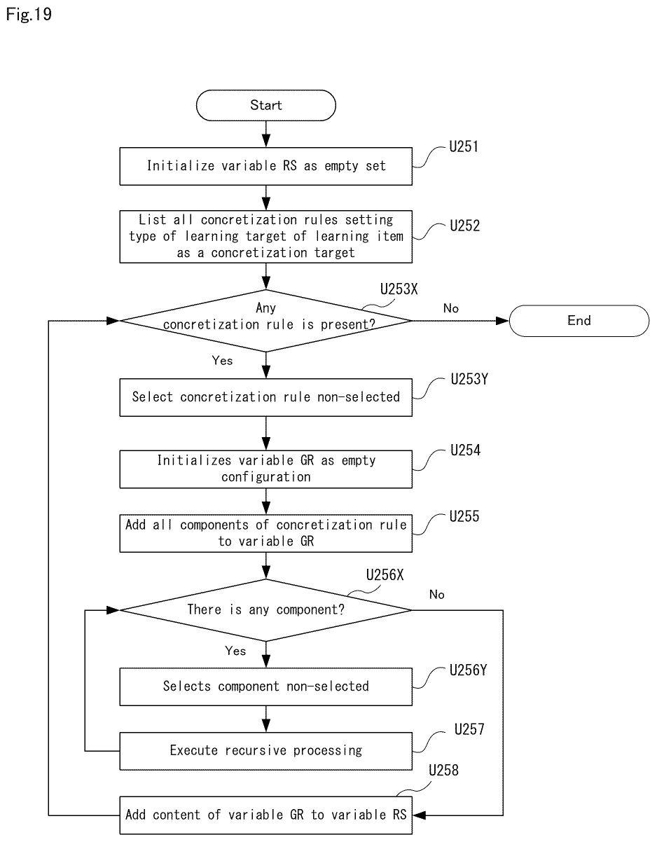

The operation of step U25 of generating a set of requirements for learning the selected learning item is described in detail with reference to FIG. 19. The unit that performs the operation in step U25 is the curriculum generation unit 227 unless otherwise noted.

First, as illustrated in FIG. 19, the curriculum generation unit 227 initializes a variable RS representing a generated set of requirements as an empty set (step U251). Then, the curriculum generation unit 227 lists all concretization rules with the configuration element type that is the learning target of the selected learning item, as a concretization target (step U252).

Furthermore, the curriculum generation unit 227 determines whether or not any concretization rule that has not been completely processed is included in the concretization rules listed in step U252 (step U253X). If the result of the determination in step U253X indicates that there is no concretization rule that has not been completely processed, step U25 is ended.

On the other hand, if the result of the determination in step U253X indicates that there is still any concretization rule that has not been completely processed, the curriculum generation unit 227 executes the operations in steps U253Y to U258, which will be described below, on the unprocessed concretization rules listed in step U252.

First, the curriculum generation unit 227 selects one concretization rule from the unprocessed concretization rules listed in step U252 (step U253Y). Then, the curriculum generation unit 227 initializes a variable GR representing the generated requirements as an empty configuration (step U254).

Furthermore, the curriculum generation unit 227 adds configuration elements to be concretized of the concretization rule selected in step U253Y and all configuration elements contained in a configuration required for the concretization to the configuration stored in the variable GR (step U255).

Then, the curriculum generation unit 227 determines whether or not the concretization rule selected in step U253Y includes any configuration element that is required for the concretization or that is contained in the configuration after the concretization (step U256X).

If the result of the determination in step U256X indicates that there is no such configuration element, the curriculum generation unit 227 executes later-described step U258. On the other hand, if the result of the determination in step U256X indicates that there is any such configuration element, the curriculum generation unit 227 performs operations in steps U256Y to U257, which will be described later.

First, the curriculum generation unit 227 selects one configuration element from the configuration elements of the concretization rule selected in step U253Y that are required for the concretization or that are included in the configuration after the concretization (step U256Y). Then, the curriculum generation unit 227 executes later-described recursive processing with the configuration element selected in step U256Y and the content of the variable GR as arguments (step U257).

Then, if the result in step U256X is No, the curriculum generation unit 227 adds the requirements stored in the variable GR representing generated requirements to a set of requirements stored in the variable RS representing the set of generated requirements (step U258).

The following will describe the operation of step U257 of recursively processing the configuration element required for the concretization of the concretization rules or the configuration element contained in the configuration after the concretization in detail with reference to FIG. 20, the operation being included in the operation of the generating a set of requirements for use in learning the selected learning items. The unit that performs the operation in step U257 is the curriculum generation unit 227 unless otherwise noted. The recursive processing in step U257 is processing with configuration elements and configurations as arguments.

First, as illustrated in FIG. 20, the curriculum generation unit 227 selects, using a suitable method, one concretization rule from the concretization rules in which the configuration element type received as an argument serves as a concretization target (step E21). Then, the curriculum generation unit 227 determines whether or not to add the concretization target of the concretization rule selected in step E21 to the configuration received as an argument (step E22). Specifically, in step E22, the curriculum generation unit 227 determines whether or not the concretization target of the concretization rule selected in step E21 is not included in the configuration received as an argument and is referenced in the configuration required for the concretization of the concretization rule.

If the result of the determination in step E22 indicates that the concretization target should not be added to the configuration received as an argument (No in step E22), the curriculum generation unit 227 executes later-described step E24.

On the other hand, if the result of the determination in step E22 indicates that the concretization target should be added to the configuration received as an argument (Yes in step E22), the curriculum generation unit 227 adds the concretization target to the configuration received as an argument (step E23).

Furthermore, after the execution in step E23 or if the result in step E22 is No, the curriculum generation unit 227 adds all configuration elements included in the configuration required for the concretization of the concretization rule selected in step E21 to the configuration received as an argument (step E24).

Then, the curriculum generation unit 227 determines whether or not an unprocessed configuration element remains in the configuration elements included in the configuration required 20) for the concretization of the concretization rule selected in step E21 or in the configuration after this concretization (step E25X).

If the result of the determination in step E25X indicates that no unprocessed configuration element remains, step U257 is ended. On the other hand, if the result of the determination in step E25X indicates that an unprocessed configuration element remains, the curriculum generation unit 227 performs operations in steps E25Y to E26, which will be described later.

First, the curriculum generation unit 227 selects one configuration element from the configuration elements included in the configuration required for the concretization of the concretization rule selected in step E21 or in the configuration after this concretization (step E25Y). Then, the curriculum generation unit 227 executes later-described recursive processing with the configuration element selected in step E25Y and the configuration received as an argument, as arguments (step E26).

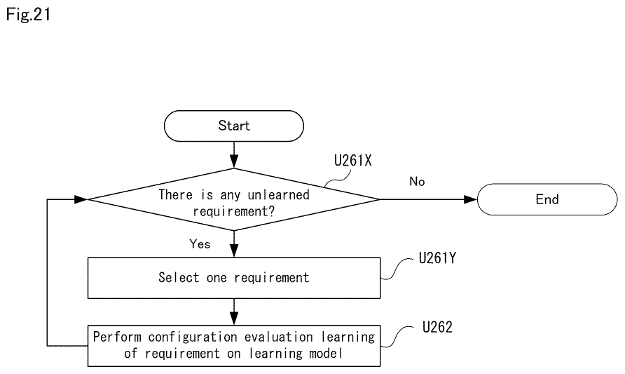

The operation of step U26 of learning the learning item using the generated set of requirements is described in detail with reference to FIG. 21.

As illustrated in FIG. 21, first, the learning process control unit 221 determines whether or not there is any unlearned requirement among the requirements contained in the generated set of requirements (step U261X). If the result of the determination in step U261X indicates that there is no unlearned requirement, step U26 is ended.

On the other hand, if the result of the determination in step U261X indicates that there is any unlearned requirement, the learning process control unit 221 performs operations in steps U261Y to U262, which will be described later, on each unlearned requirement.

First, the learning process control unit 221 selects one requirement from the generated set of requirements (step U261Y). Then, the configuration element learning unit 22 performs configuration evaluation learning of the requirement on the learning model using the requirement 10) selected in step U261 as an input (step U262). The operation of the configuration evaluation learning in step U262 is the same as the configuration evaluation learning in step S1 described in Example Embodiment 1.

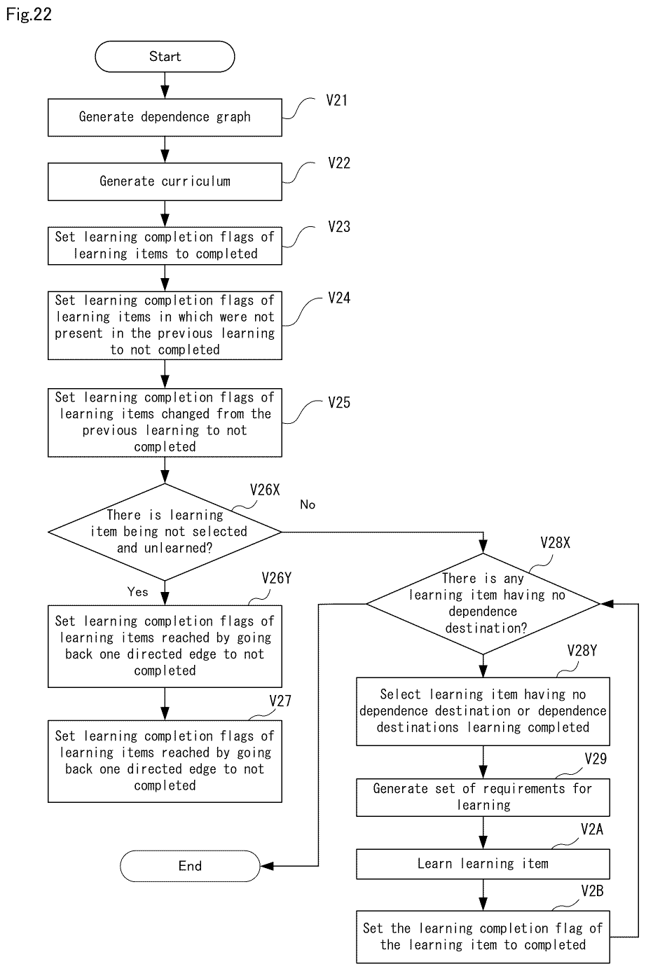

An operation V2 of re-learning of configuration evaluation in the system configuration evaluation apparatus 2 will be described in detail with reference to FIG. 22.

First, as illustrated in FIG. 22, the curriculum generation unit 227 generates a dependence graph (step V21). Details of the operation of step V21 of generating a dependence graph are the same as in step U21 illustrated in FIG. 12.

Then, the curriculum generation unit 227 generates a curriculum (step V22). Details of the operation of step V22 of generating a curriculum are the same as in step U22 illustrated in FIG. 20) 12. Then, the curriculum generation unit 227 sets learning completion flags of the learning items in the curriculum to completed (step V23).

Then, the curriculum generation unit 227 sets learning completion flags of, among the learning items contained in the curriculum, all of learning items whose learning targets are configuration element types that were not present in the previous learning to not completed (step V24). As an example of the detailed method in step V24, a method in which the curriculum at the previous learning is stored and compared to the current curriculum, and the learning completion flags of the learning items present only in the current curriculum are set to not completed is suitable, but the present invention is not limited to this method.

Then, the curriculum generation unit 227 sets the learning completion flags of, among the learning items contained in the curriculum, all of learning items whose learning targets are configuration element types with their definitions changed from the previous learning to not completed (step V25). As an example of the detailed method in step V25, a method in which generation date of the curriculum at the previous learning and the update date of the configuration element type definition information are stored, and the learning completion flag for learning items of the configuration element type whose definition information update date is later than the curriculum generation date at the previous learning is set to not completed is suitable, but the present invention is not limited to this method.

The curriculum generation unit 227 then determines whether or not the learning items included in the curriculum includes any learning item that is not selected and unlearned (step V26X).

On the other hand, if the result of the determination in step V26X indicates that there is any unlearned learning item, the curriculum generation unit 227 performs operations in steps V26Y to V27, which will be described later, until all the learning items with a learning completion flag 10) set to “not completed” are selected.

First, the curriculum generation unit 227 selects one learning item with a learning completion flag set to “not completed” from the learning items contained in the curriculum (step V26Y). Then, the curriculum generation unit 227 sets the learning completion flags of learning items that can be reached by going back one directed edge, among the directed edges in the curriculum, from the learning item selected in step V26Y, to not completed (step V27). Then, the curriculum generation unit 227 executes the determination in step V26X again.

Also, if the result of the determination in step V26X indicates that there is no unlearned learning item, the curriculum generation unit 227 determines whether or not there is any learning item that has no dependence destination or has dependence destinations all having a learning completion flag set to “completed” (step V28X).

If the result of the determination in step V28X indicates that there is no learning item that has no dependence destination or has dependence destinations all having a learning completion flag set to “completed”, the operation V2 is ended. On the other hand, if the result of the determination in step V28X indicates that there is any learning item that has no dependence destination or has dependence destinations all having a learning completion flag set to “completed”, operations in steps V28Y to U2B, which will be described later, are executed.

First, the learning process control unit 221 selects, from the curriculum, one learning item that has no dependence destination or has dependence destinations all having a learning completion flag set to “completed” (step V28Y).

Then, the curriculum generation unit 227 generates a set of requirements for learning the learning item selected in step V28Y (step V29). Details of the operation of step V29 of generating a set of requirements for learning the learning item are the same as in step U25 illustrated in FIG. 12.

Furthermore, the configuration element learning unit 22 learns the learning item selected in step V28Y using the set of requirements generated in step V29 (step V2A). Then, the learning process control unit 221 sets the learning completion flag of the learning item selected in step V28Y to completed (step V2B). Details of the operation of step V2A of learning the learning item using the set of requirements are the same as in step U26 illustrated in FIG. 12.

Note that also in Example Embodiment 2, the configuration evaluation operation T2 is the same as the configuration evaluation operation T1 in Example Embodiment 1.

### [Description of Effects]

According to Example Embodiment 2, learning efficiency is improved by learning evaluation values of configuration elements in an appropriate order. In Example Embodiment 2, configuration elements are learned in the order in accordance with a curriculum based on a dependency relationship. Accordingly, learning of specific configuration elements is possible after the completion of learning of other configuration elements that requires prior learning to learn the specific configuration elements. Also, according to Example Embodiment 2, it is possible to reduce time for learning by skipping the learning of learned configuration elements. As a result, the learning efficiency is improved.

### [Program]

In Example Embodiment 2, the program need only to be a program that causes a computer to execute the steps illustrated in FIGS. 12 to 22. By installing this program into the computer and executing the program, it is possible to realize the system configuration evaluation apparatus 2 and the system configuration evaluation method. In this case, a processor of the computer functions as the configuration evaluation unit 21 and the configuration element learning unit 22 and executes the processing. Examples of the computer include, in addition to a general-purpose PC, a smartphone and a tablet-type terminal device.

Also, the program may be executed by a computer system constituted by a plurality of computers. In this case, for example, one or more computers may function as the configuration evaluation unit 21 or the configuration element learning unit 22.

### Example Embodiment 3

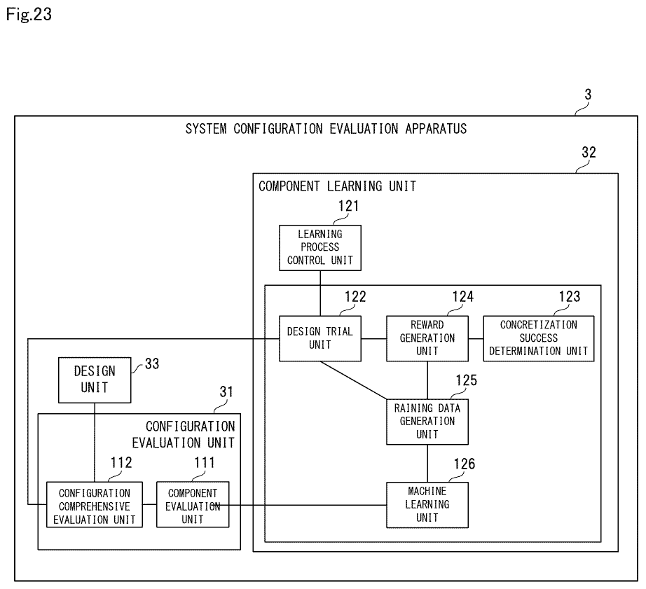

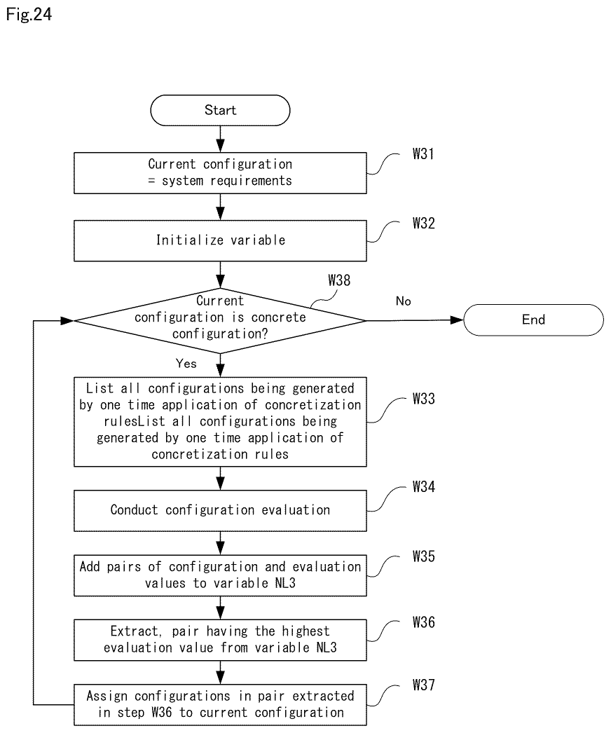

The following will describe a system configuration evaluation apparatus, a system configuration evaluation method, and a program according to Example Embodiment 3 with reference to FIGS. 23 to 24.

### [Apparatus Configuration]

First, a configuration of the system configuration evaluation apparatus according to Example Embodiment 3 is described with reference to FIG. 23. FIG. 23 is a configuration diagram illustrating an example of a configuration of the system configuration evaluation apparatus.

As illustrated in FIG. 23, the system configuration evaluation apparatus 3 includes a configuration evaluation unit 31, a configuration element learning unit 32, and a design unit 33. Furthermore, the configuration evaluation unit 31 includes the configuration element evaluation unit 111 and the configuration comprehensive evaluation unit 112. The configuration element learning unit 32 includes the learning process control unit 121, the design trial unit 122, the concretization success determination unit 123, the reward generation unit 124, the training data generation unit 125, and the machine learning unit 126. These units operate substantially as follows.

The configuration element evaluation unit 111, the configuration comprehensive evaluation unit 112, the learning process control unit 121, the design trial unit 122, the concretization success determination unit 123, the reward generation unit 124, the training data generation unit 125, and the machine learning unit 126, and overviews of the operations thereof are the same as the operations of the corresponding units described in Example Embodiment 1.

However, in Example Embodiment 3, as described above, the system configuration evaluation apparatus 3 includes the design unit 33, and Example Embodiment 3 differs from Example Embodiment 1 in this respect. The design unit 33 determines the configuration to be searched for in a design space of the computer system based on the evaluation values output from the configuration comprehensive evaluation unit 112, and designs the system configuration using the determined configuration.

### [Apparatus Operations]

The following will describe an example of the operation of the system configuration evaluation apparatus 3 according to Example Embodiment 3 with reference to FIG. 24. In the following description, FIG. 23 is referenced as appropriate. Also, in Example Embodiment 3, a system configuration evaluation method is executed by operating the system configuration evaluation apparatus 3. Accordingly, in Example embodiment 3, description of the system configuration evaluation method is replaced with the following description on the operation of the system configuration evaluation apparatus.

In Example Embodiment 3, the operations are broadly divided into three operations. The three operations include operations of configuration evaluation learning, configuration evaluation, and design. In the operation of configuration evaluation learning, training of a learning model relating to evaluation of an ICT system in units of configuration elements is performed to evaluate the configuration of the computer system, specifically, the ICT system. In the operation of configuration evaluation, the trained learning model is used to evaluate the configuration of the ICT system. In the operation of design, a concretized ICT system is obtained by searching for a method for concretizing abstract requirements in a stepwise manner. In the search, the direction of search is determined based on the result of the configuration evaluation. The following will describe the operations.

First, in Example Embodiment 3, a configuration evaluation learning operation S3 is the same operation as the configuration evaluation learning operation S1 in Example Embodiment 1. Furthermore, in Example Embodiment 3, a configuration evaluation operation T3 is the same operation as the configuration evaluation operation T1 in Example Embodiment 1.

A design operation W3 of the example embodiment is described in detail with reference to FIG. 24. The unit that performs the design operation W3 is the design unit 33 unless otherwise noted.

As illustrated in FIG. 24, first, the design unit 33 assigns requirements to be designed to a variable representing the current configuration (step W31). Hereinafter, content assigned to the variable representing the current configuration is expressed simply by “current configuration”. Then, the design unit 33 initializes a variable NL3, which stores a configuration candidate to be next assigned to the variable representing the current configuration, as an empty list (step W32).

Then, the design unit 33 determines whether or not the current configuration is a concrete configuration (step W38). If the result of the determination in step W38 indicates that the current configuration is a concrete configuration, the operation W3 is ended. On the other hand, if the result of the determination in step W38 indicates that the current configuration is not a concrete 20) configuration, the design unit 33 lists all configurations that can be generated from the current configuration by one time application of concretization rules (step W33).

Furthermore, the design unit 33 inputs the configurations listed in step W33 to the configuration comprehensive evaluation unit 112, and causes the configuration comprehensive evaluation unit 112 to conduct configuration evaluation (step W34). The operation in step W34 is the configuration evaluation operation T3. That is, the operation in step W34 is the same as the configuration evaluation operation T1 described in Example Embodiment 1.

Then, the design unit 33 adds pairs of one of configurations listed in step W33 and the evaluation values of the corresponding configuration obtained in step W34 to the list that the variable NL3 stores (step W35).

Then, the design unit 33 extracts, from the list that the variable NL3 stores, the pair having the highest evaluation value (step W36). Furthermore, the design unit 33 assigns the configuration contained in the pair extracted in step W36 to the variable representing the current configuration (step W37).

With this, steps W33 to W37 are repeatedly executed until the current configuration is a concrete configuration.

### [Description of Effects]

According to Example Embodiment 3, it is possible to realize automated design of an ICT system using a learning model obtained by efficient learning. In Example Embodiment 3, the learning model trained in Example Embodiment 1 can be used for design in the configuration element evaluation unit 111.

### [Program]

In Example Embodiment 3, a program need only be a program that causes a computer to execute the steps illustrated in FIGS. 3 to 10 and 24. By installing this program into the computer 10) and executing the program, it is possible to realize the system configuration evaluation apparatus 3 and the system configuration evaluation method. In this case, a processor of the computer functions as the configuration evaluation unit 31, the configuration element learning unit 32, and the design unit 33, and executes the processing. Examples of the computer include, in addition to a general-purpose PC, a smartphone and a tablet-type terminal device.

Also, the program may be executed by a computer system constituted by a plurality of computers. In this case, for example, one or more computers may function as any one of the configuration evaluation unit 31, the configuration element learning unit 32, and the design unit 33.

### Example Embodiment 4

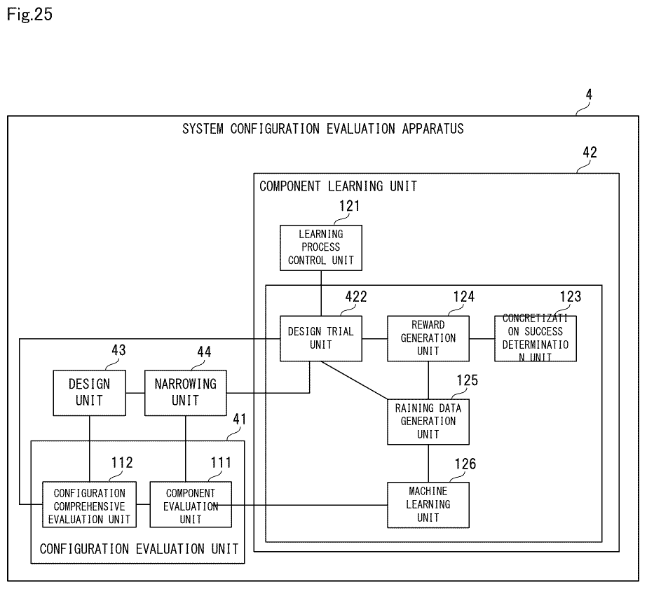

The following will describe a system configuration evaluation apparatus, a system configuration evaluation method, and a program according to Example Embodiment 4 with reference to FIGS. 25 to 29. In Example Embodiment 4, configuration drafts generated in the process of design are narrowed down. In Example Embodiment 4, the same descriptions as those in Example Embodiment 1 are omitted as appropriate.

### [Apparatus Configuration]

First, a configuration of the system configuration evaluation apparatus according to Example Embodiment 4 is described with reference to FIG. 25. FIG. 25 is a configuration diagram illustrating an example of a configuration of the system configuration evaluation apparatus.

As illustrated in FIG. 25, the system configuration evaluation apparatus 4 includes a configuration evaluation unit 41, a configuration element learning unit 42, a design unit 43, and a narrowing unit 44. The configuration evaluation unit 41 includes the configuration element evaluation unit 111 and the configuration comprehensive evaluation unit 112. The configuration element learning unit 42 includes the learning process control unit 121, a design trial unit 422, the concretization success determination unit 123, the reward generation unit 124, the training data generation unit 125, and the machine learning unit 126. These units operate substantially as follows.

The configuration element evaluation unit 111, the configuration comprehensive evaluation unit 112, the learning process control unit 121, the concretization success determination unit 123, the reward generation unit 124, the training data generation unit 125, and the machine learning unit 126, and overviews of the operations thereof are the same as the operations of the corresponding units described in Example Embodiments 1 and 3.

In Example Embodiment 4, when generating a candidate configuration to be searched for in the process of design, the narrowing unit 44 determines configuration elements to be concretized based on the evaluation values of configuration elements output by the configuration element evaluation unit, and generates only a configuration obtained by concretization of the determined configuration elements.

Also, the design trial unit 422 trials design of the computer system, and collects configurations obtained throughout the designing from start to finish. An overview of the operation of the design trial unit 422 is also the same as the operation described in Example Embodiments 1 and 3. However, in Example Embodiment 4, when adding a configuration (candidate) to be searched for during the process of design, the design trial unit 422 adds only the configurations generated by the narrowing unit 44.

The design unit 43 determines a configuration to be searched for in a design space of the computer system based on the evaluation values output from the configuration comprehensive evaluation unit 112, and designs the system configuration of the computer system using the determined configurations. The operation of the design unit 43 is the same as the operation described in Example Embodiment 3. However, in Example Embodiment 4, when adding a configuration (candidate) to be searched for during the design process, the design unit 43 adds only the configuration generated by the narrowing unit 44.

### [Apparatus Operations]

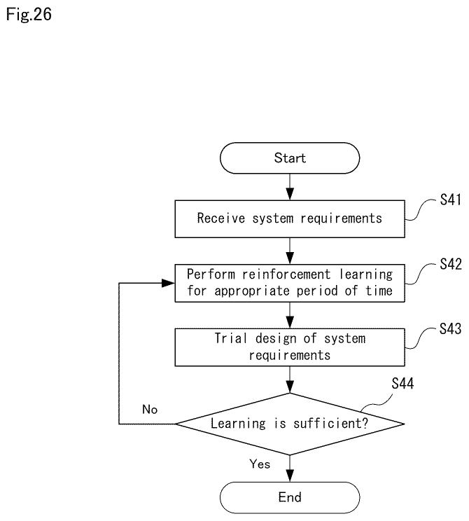

The following will describe an example of the operation of the system configuration evaluation apparatus 4 according to Example Embodiment 4 with reference to FIGS. 26 to 29. In the following description, FIG. 25 is referenced as appropriate. Also, in Example Embodiment 4, a system configuration evaluation method is executed by operating the system configuration evaluation apparatus 4. Accordingly, in Example embodiment 4, description of the system configuration evaluation method is replaced with the following description on the operation of the system configuration evaluation apparatus.

In Example Embodiment 4, the operations are broadly divided into three operations. The three operations include an operation of configuration evaluation learning, an operation of configuration evaluation, and an operation of design. In the operation of configuration evaluation learning, training of a learning model relating to evaluation of an ICT system in units of configuration elements is performed to evaluate the configuration of the computer system, specifically, the ICT system. In the operation of configuration evaluation, the trained learning model is used to evaluate the system configuration of the ICT system. In the operation of design, a concretized ICT system is obtained by searching for a method for concretizing abstract requirements in a stepwise manner. In the search, the direction of search is determined based on the result of the configuration evaluation. The following will describe the operations.

A configuration evaluation learning operation S4 is described in detail with reference to FIG. 26. In view of the granularity of FIG. 26, the configuration evaluation learning operation S4 is the same as the configuration evaluation learning operation S1 described in Example Embodiment 1. However, in a finer flowchart granularity, the operation S4 may differ from the operation S1 in later-described step S42. The difference will be described separately. Operations other than step S42 are the same as the configuration evaluation learning operation S1 described in Example Embodiment 1 also in the finer granularity.

First, as illustrated in FIG. 26, the configuration element learning unit 42 receives system requirements R4 to be learned as an input (step S41). Then, the configuration element learning unit 42 performs reinforcement learning for an appropriate period of time using the system requirements R4 (step S42). The appropriate period of time in this context may be determined as appropriate based on learning time and the number of times of learning (in the case of, e.g., reinforcement learning using a neural network, the number of update of weighting of the neural network). Note that an appropriate period of time is not particularly limited.

Furthermore, the design trial unit 422 trials design of the system requirements R4 using the current learning model (in the case of reinforcement learning using, e.g., a neural network, the neural network) (step S43). As the design method, for example, the design method disclosed in Patent Document 1 is exemplified, but the design method is not particularly limited in Example Embodiment 4.

Then, based on the result of step S13, the learning process control unit 121 determines whether or not learning is sufficient (step S44). The determination method in step S44 depends on the design method in step S43. For example, if step S43 is executed by the method disclosed in Patent Document 1, an example of the design method is a method of determining it is sufficient when the number of searching steps in design is a predetermined value or more. Furthermore, a method of determining it is sufficient when, in design in step S43 executed in the past, the number of searching steps was less than the predetermined number for a specified number of times in a row is also exemplified. The determination method in step S44 is not limited to them.

If the result of the determination in step S44 indicates that learning is sufficient, the operation S4 is ended. On the other hand, if the result of the determination in step S44 indicates that the learning is not sufficient, step S42 is executed again. That is, steps S42 to S43 are repeated until the learning is determined to be sufficient in step S44.

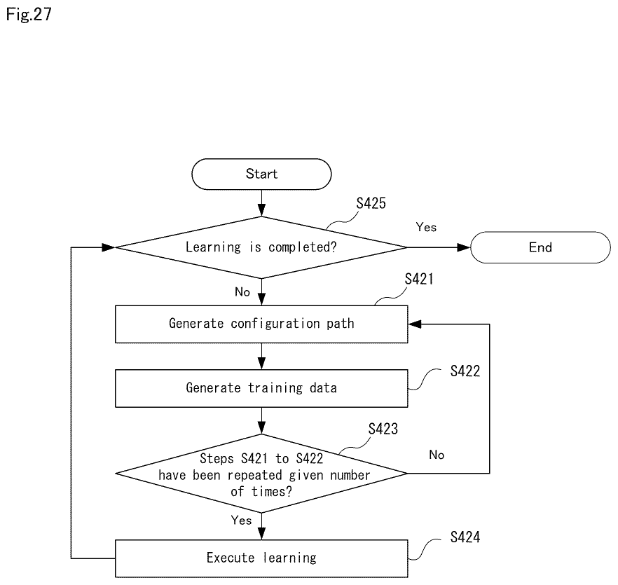

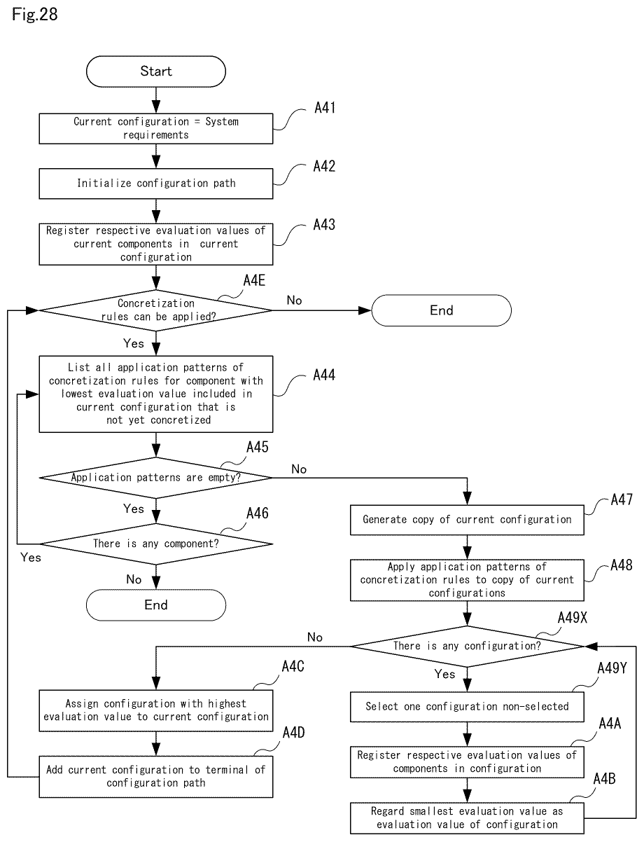

The operation of step S42 of performing reinforcement learning is described in detail with reference to FIG. 27. In view of the granularity of FIG. 28, the operation of step S42 is the same as the operation of step S12 described in Example Embodiment 1. However, in a finer flowchart granularity, step S42 differs from S12 in later-described step S421, which will be described separately. Operations other than step S421 are the same as the configuration evaluation learning operation S1 described in Example Embodiment 1 also in the finer granularity.

Also, the operation described here is an example of the operation for learning the design method relating to the functional requirements of the system, and is not limited to the description here as long as the learning of design methods relating to the functional requirements of the system is realized. Also, an example of the design method is the design method disclosed in Patent Document 1, but the design method is not particularly limited in Example Embodiment 4.

As illustrated in FIG. 27, first, the design trial unit 422 trials design using the system requirements R4 and generates a configuration path CP1 (step S421). Then, the training data generation unit 125 generates training data (step S422).

Then, the design trial unit 422 determines whether or not steps S421 to S422 have been repeated a given number of times (step S423). If the result of the determination in step S423 indicates that steps S421 to S422 are not repeated the given number of times, the design trial unit 422 executes step S421 again.

On the other hand, if the result of the determination in step S423 indicates that steps S421 to S422 have been repeated the given number of times, the machine learning unit 126 executes learning based on the training data (step S424).

Then, the machine learning unit 126 determines whether or not the learning is completed, that is, whether or not the learning has been executed for an appropriate period of time (step S425). If the result of the determination in step S425 indicates that the learning is not completed, steps S421 and S424 are executed again. On the other hand, if the result of the determination in step S425 indicates that the learning is completed, step S42 is ended.

The appropriate period of time in this context may be determined based on learning time, the number of times of learning, and in the case of reinforcement learning using, e.g., a neural network, the number of update of weighting of the neural network. However, in Example Embodiment 4, the appropriate period of time may also be determined based on other factors.

The operation of step S421 of generating a configuration path is described in detail with reference to FIG. 28. The unit that performs the operation in step S421 is the design trial unit 422 unless otherwise noted.

As illustrated in FIG. 28, first, the design trial unit 422 assigns the system requirements R4 to a variable representing the current configuration (step A41). Hereinafter, content assigned to the variable representing the current configuration is expressed simply by “current configuration”.

Then, the design trial unit 422 initializes the configuration path CP4 as a variable in a list type data structure containing only the current configuration as content (step A42). Note here that a case where the data structure of the configuration path CP4 is of the list type is given as an example, but the data structure may be of any type other than the list type as long as it is a data structure that can store multiple contents of the same type in a definite order.

Furthermore, the design trial unit 422 inputs the current configuration to the configuration element evaluation unit 111, and registers the obtained respective evaluation values of the configuration elements in the current configuration (step A43).

Then, the design trial unit 422 determines whether or not the concretization rules can be applied to the current configuration (step A4E). If the result of the determination in step A4E 20) indicates that the concretization rules cannot be applied, step S421 is ended.

On the other hand, if the result of the determination in step A4E indicates that the concretization rules can be applied, the narrowing unit 44 lists all application patterns of concretization rules for the configuration element with the lowest evaluation value included in the current configuration that is not yet concretized (step A44).

Then, the design trial unit 422 determines whether or not the application patterns are empty (step A45). If the result of the determination in step A45 indicates that the application patterns are empty (Yes in step A45), the design trial unit 422 further determines whether or not there is any configuration element on which the determination in step A44 has not been performed (step A46).

If the result of the determination in step A46 indicates that there is any configuration element (Yes in step A46), the design trial unit 422 executes step A44 again. On the other hand, if the result of the determination in step A46 indicates that there is no such configuration element (No in step A46), the entire operation in step S421 is ended.

Also, if the result of the determination in step A45 indicates that the application patterns are not empty (No in step A45), the narrowing unit 44 generates the same number of copies of the current configuration as the number of application patterns of the concretization rules listed in step A44 (step A47).

Furthermore, the narrowing unit 44 lists all the configurations obtained as a result of applying the application patterns of the concretization rules listed in step A44 to the respective different copies of the current configurations generated in step A47 (step A48).

Then, the narrowing unit 44 determines whether or not there is any configuration that has not yet been selected in later-described step A49Y (step A49X). If the result of the determination in step A49X indicates that there is such a configuration, the narrowing unit 44 selects one configuration from the configuration listed in step A48 (step A49Y).

Then, the narrowing unit 44 inputs the configuration selected in step A49Y to the configuration element evaluation unit 111, and registers the obtained respective evaluation values of the configuration elements in this configuration (step A4A). Furthermore, the narrowing unit 44 regards, among the evaluation values of the configuration elements obtained in step A4A, the smallest evaluation value as the evaluation value of the configuration selected in step A49Y (step A4B). Then, the narrowing unit 44 executes the determination in step A49X again.

Also, if the result of the determination in step A49X indicates that there is no such a configuration, the narrowing unit 44 assigns the configuration with the highest evaluation value among the configurations listed in step A48 to the variable representing the current configuration 20) (step A4C). Then, the narrowing unit 44 adds the current configuration to the terminal of the configuration path CP4 (step A4D). Then, the narrowing unit 44 executes the determination of step A4E and repeats steps A44 to A4D until the concretization rules can no longer be applied to the current configuration.

The configuration evaluation operation in Example Embodiment 4 is the same as in Example Embodiment 3, and that is to say, the configuration evaluation operation in Example Embodiment 4 is the same as the configuration evaluation operation T1 in Example Embodiment 1.

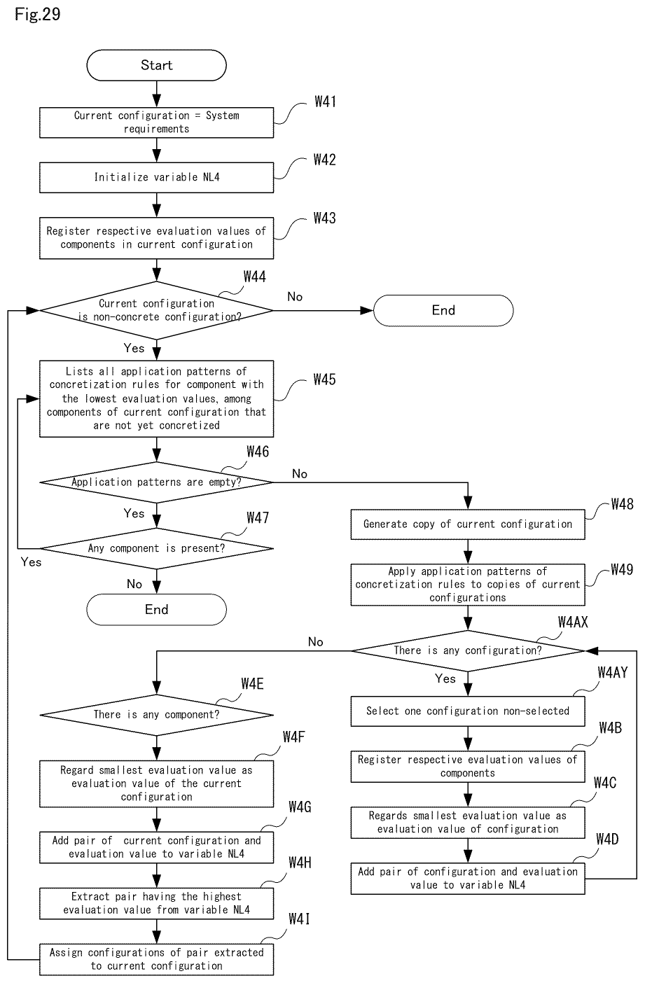

A design operation W4 of the example embodiment is described in detail with reference to FIG. 29. The unit that performs the design operation W4 is the design unit 43 unless otherwise noted.

As illustrated in FIG. 29, first, the design unit 43 assigns requirements to be designed to the variable representing the current configuration (step W41). Hereinafter, content of the variable representing the current configuration is expressed simply by “current configuration”.

Then, the design unit 43 initializes a variable NL4, which stores a configuration candidate to be next assigned to the variable representing the current configuration, as an empty list (step W42). Then, the design unit 43 inputs the current configuration to the configuration element evaluation unit 111, and registers the obtained respective evaluation values of the configuration elements in the current configuration (step W43).

Subsequently, the design unit 43 determines whether or not the current configuration is a non-concrete configuration (step W44). If the result of the determination in step W44 indicates that the current configuration is a concrete configuration, the operation in step W4 is ended. On the other hand, if the result of the determination in step W44 indicates that the current configuration is a non-concrete configuration, the design unit 43 executes the operations in steps W45 to W4I, which will be described later, until the current configuration is a concrete configuration.

First, the narrowing unit 44 lists all application patterns of concretization rules for the configuration element with the lowest evaluation values, among configuration elements of the current configuration that are not yet concretized (step W45). The configuration elements serving as the targets in step W45 are handled as being concretization targets.

Then, the design unit 43 determines whether or not the application patterns are empty (step W46). If the result of the determination in step W46 indicates that the application patterns are empty (Yes in step W46), the design unit 43 determines whether or not the current configuration includes any configuration element that has not been served as a concretization target (step W47).

If the result of the determination in step W47 indicates that the current configuration does not include any configuration element that has not been served as a concretization target (No in step W47), the operation W4 is ended, and the procedure moves to step W4H. On the other hand, if the result of the determination in step W47 indicates that the current configuration includes any configuration element that has not been served as a concretization target (Yes in step W47), the design unit 43 executes step W45 again.

Also, if the result of the determination in step W46 indicates that the application patterns are not empty (No in step W46), the narrowing unit 44 generates the same number of copies of the current configuration as the number of application patterns of the concretization rules listed in step W45 (step W48).

Furthermore, the narrowing unit 44 lists all the configurations obtained as a result of applying the application patterns of the concretization rules listed in step W45 to the respective different copies of the current configurations generated in step W48 (step W49).

Then, the design unit 43 determines whether or not, among the configurations listed in step W49, there is any configuration on which later-described steps W4AY to W4D have not yet been executed (step W4AX).

If the result of the determination in step W4AX indicates that there is any configuration on which later-described steps W4AY to W4D have not yet been executed, the design unit 43 selects one configuration from the configurations listed in step W49 (step W4AY). Then, the design unit 43 inputs the configuration selected in step W4AY to the configuration element evaluation unit 111, and registers the obtained respective evaluation values of the configuration elements in this configuration (step W4B).

Furthermore, the design unit 43 regards, among the evaluation values of the configuration elements obtained in step W4B, the smallest evaluation value as the evaluation value of the configuration selected in step W4AY (step W4C). Then, a pair of the configuration selected in step W4AY and the evaluation value of this configuration obtained by the configuration element evaluation unit 111 in step W4C is added to the list that the variable NL4 stores (step W4D). Then, the design unit 43 executes the determination in step W4AX again.

Also, if the result of the determination in step W4AX indicates that there is no configuration on which steps W4AY to W4D have not been executed, the design unit 43 determines whether or not the current configuration includes any configuration element that has not been served as a concretization target (step W4E).

If the result of the determination in step W4E indicates that the current configuration includes any configuration element that has not been served as a concretization target (Yes in step W4E), the design unit 43 regards the smallest evaluation value of the configuration elements 20) contained in the current configuration as the evaluation value of the current configuration (step W4F). Then, the design unit 43 adds a pair of the current configuration and the evaluation value of this current configuration obtained in step W4G to the list that the variable NL4 stores (step W4G).

Then, after step W4G is executed, or if the result of the determination in step W4E indicates that the current configuration does not include any configuration element that has not been served as a concretization target (No in step W4E), the design unit 43 executes step W4H.

In step W4H, the design unit 43 extracts, from the list in which the variable NL4 is stored, the pair having the highest evaluation value (step W4H). Furthermore, the design unit 43 assigns the configurations contained in the pair extracted in step W4H to the variable representing the current configuration (step W4I). Then, the design unit 43 executes the determination in step W44 again.

### [Description of Effects]

According to Example Embodiment 4, it is possible to realize automated design of a computer system, specifically, an ICT system, as well as an improvement in learning efficiency thereof. In Example Embodiment 4, by narrowing down configurations to be generated for each step of searching for automated design and learning thereof, the number of configurations to be generated in each of the searching steps can be reduced. Accordingly, time for each searching step is reduced, resulting in an improvement in efficiency. Also, narrowing down is performed such that the configuration elements with the lowest probability that concretization will be successfully completed are to be concretized first, and thus concretization that increases the probability of success of design of the overall system configuration is likely to be selected, resulting in an improvement in searching accuracy. As a result, the learning efficiency is improved.

### [Program]

In Example Embodiment 4, a program need only be a program that causes a computer to execute the steps illustrated in FIGS. 6 to 10 and 26 to 29. By installing this program into the computer and executing the program, it is possible to realize the system configuration evaluation apparatus 1 and the system configuration evaluation method. In this case, a processor of the computer functions as the configuration evaluation unit 41, the configuration element learning unit 42, the design unit 43, and the narrowing unit 44, and executes the processing. Examples of the computer include, in addition to a general-purpose PC, a smartphone and a tablet-type terminal device.

Also, the program may be executed by a computer system constituted by a plurality of computers. In this case, for example, one or more computers may function as any one of the configuration evaluation unit 41, the configuration element learning unit 42, the design unit 43, and the narrowing unit 44.

### [Physical Configuration]

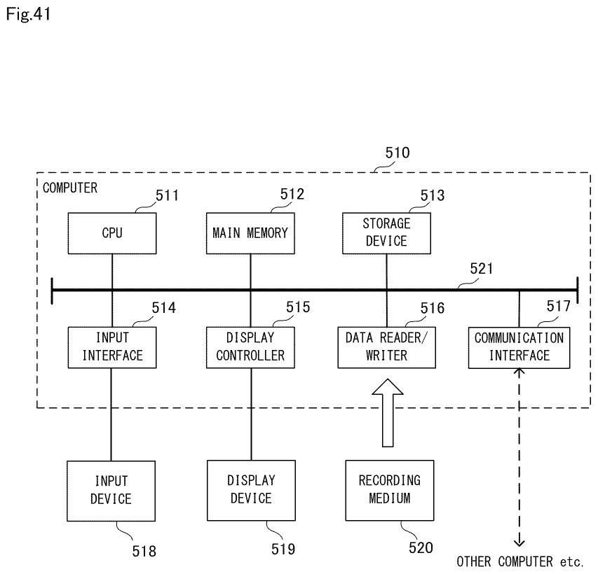

Here, a computer that realizes the system configuration evaluation apparatus by executing the program according to the example embodiment 1 to 4 will be described with reference to FIG. 41. FIG. 41 is a block diagram illustrating an example of a computer that realizes the system configuration evaluation apparatus.

As illustrated in FIG. 41, a computer 510 includes a CPU 511, a main memory 512, a storage device 513, an input interface 514, a display controller 515, a data reader/writer 516, and a communication interface 517. These units are connected via a bus 521 so as to be able to perform data communication with each other.

the computer 510 may include a GPU (Graphics Processing Unit) or a FPGA (Field-Programmable Gate Array) in addition to the CPU 511 or instead of the CPU 511. In this case, the GPU or the FPGA may execute the program.

The CPU 511 loads programs (codes) according to the present example embodiment stored in the storage device 513 to the main memory 512, and executes the programs in a predetermined order to perform various kinds of calculations. The main memory 512 is typically a volatile storage device such as a DRAM (Dynamic Random Access Memory).

Also, the program according to the present example embodiment is provided in the state of being stored in a computer-readable recording medium 520. Note that programs according to the present example embodiment may be distributed on the Internet that is connected via the communication interface 517.

Specific examples of the storage device 513 include a hard disk drive, and a semiconductor storage device such as a flash memory. The input interface 514 mediates data transmission between the CPU 511 and an input device 518 such as a keyboard or a mouse. The display controller 515 is connected to a display device 519 and controls the display of the display device 519.

The data reader/writer 516 mediates data transmission between the CPU 511 and the recording medium 520, reads out programs from the recording medium 520, and writes the results of processing performed by the computer 510 to the recording medium 520. The communication interface 517 mediates data transmission between the CPU 511 and another computer.

Specific examples of the recording medium 520 include general-purpose semiconductor storage devices such as a CF (Compact Flash (registered trademark)) and a SD (Secure Digital), a magnetic recording medium such as a flexible disk, and an optical recording medium such as a CD-ROM (Compact Disk Read Only Memory).

Note that the system configuration evaluation apparatus can also be realized by using hardware (for example, circuits) corresponding to the units, in place of a computer that has programs installed therein. Furthermore, a configuration may also be adopted in which a portion of the system configuration evaluation apparatus is realized by programs, and the remaining portion of the system configuration evaluation apparatus is realized by hardware.

One or all of the above-described example embodiments can be expressed as, but are not limited to, Supplementary Note 1 to Supplementary Note 18 described below.

### (Supplementary Note 1)

A system configuration evaluation apparatus includes:
a configuration evaluation unit configured to output, using a learning model, evaluation values of configuration elements of a computer system, and further output an evaluation value of the entire computer system obtained by integrating the output evaluation values; and
a configuration element learning unit configured to trial design of the computer system based on preset requirements, determine, with respect to configurations obtained throughout the designing from start to finish, whether or not configuration elements included in the configurations are concretized according to the requirements, generate training data for the learning model based on a determination result, and execute machine learning on the learning model using the generated training data.

### (Supplementary Note 2)

The system configuration evaluation apparatus according to supplementary note 1,
wherein the configuration element learning unit determines whether or not the configuration elements included in each of the configurations are concretized according to the requirements, calculates rewards to be given to the configuration elements included in the corresponding configuration, based on a determination result, and generates, for each of the configurations, the configuration and the rewards to be given to the configuration elements calculated for the configuration, as the training data.

### (Supplementary Note 3)

The system configuration evaluation apparatus according to supplementary note 1,
wherein the configuration element learning unit generates a curriculum based on a dependence relationship representing a relationship between a specific configuration element and another configuration element required to concretize the specific configuration element, in a manner such that learning is performed in order of configuration elements with no dependence relationship and configuration elements with a dependence relationship for which learning is completed, and executes machine learning on the learning model in accordance with the generated curriculum.

### (Supplementary Note 4)

The system configuration evaluation apparatus according to supplementary note 1, further includes:
a design unit configured to determine, based on the evaluation values of the configuration elements output by the configuration evaluation unit, a configuration to be searched for in a design space of the computer system, and design a system configuration of the computer system using the determined configuration.

### (Supplementary Note 5)

The system configuration evaluation apparatus according to supplementary note 4, further includes:
a narrowing unit configured to determine configuration elements to be concretized, based on the evaluation values of the configuration elements output by the configuration evaluation unit, and generate only a configuration obtained by concretizing the determined configuration elements,
wherein, when adding the configuration to be searched for, the design unit adds only the configuration generated by the narrowing unit, and
the configuration element learning unit determines, in the trialing of design of the computer system, a configuration to be searched for in the design space of the computer system, trials design of the system configuration of the computer system using the determined configuration, and adds, when adding the configuration to be searched for, only the configuration generated by the narrowing unit.

### (Supplementary Note 6)

A system configuration evaluation method includes:
a configuration evaluation step of outputting, using a learning model, evaluation values of configuration elements of a computer system, and further outputting an evaluation value of the entire computer system obtained by integrating the output evaluation values; and
a configuration element learning step of trialing design of the computer system based on preset requirements, determining, with respect to configurations obtained throughout the designing from start to finish, whether or not configuration elements included in the configurations are concretized according to the requirements, generating training data for the learning model based on a determination result, and executing machine learning on the learning model using the generated training data.

### (Supplementary Note 7)

The system configuration evaluation method according to supplementary note 6,
wherein in the configuration element learning step, determining whether or not the configuration elements included in each of the configurations are concretized according to the requirements, calculating rewards to be given to the configuration elements included in the corresponding configuration, based on a determination result, and generating, for each of the configurations, the configuration and the rewards to be given to the configuration elements calculated for the configuration, as the training data.

### (Supplementary Note 8)

The system configuration evaluation method according to supplementary note 6,
wherein in the configuration element learning step, generating a curriculum based on a dependence relationship representing a relationship between a specific configuration element and another configuration element required to concretize the specific configuration element, in a manner such that learning is performed in order of configuration elements with no dependence relationship and configuration elements with a dependence relationship for which learning is completed, and executing machine learning on the learning model in accordance with the generated curriculum.

### (Supplementary Note 9)

The system configuration evaluation method according to supplementary note 6, further includes:
a design step of determining, based on the evaluation values of the configuration elements output, a configuration to be searched for in a design space of the computer system, and designing a system configuration of the computer system using the determined configuration.

### (Supplementary Note 10)

The system configuration evaluation method according to supplementary note 9, further includes:
a narrowing step of determining configuration elements to be concretized, based on the evaluation values of the configuration elements output, and generating only a configuration obtained by concretizing the determined configuration elements,
wherein, when adding the configuration to be searched for, in the design step, adding only the configuration generated, and
in the configuration element learning step, in the trialing of design of the computer system, determining a configuration to be searched for in the design space of the computer system, trialing design of the system configuration of the computer system using the determined configuration, and adding, when adding the configuration to be searched for, only the configuration generated.

### (Supplementary Note 11)

A computer readable recording medium that includes a program recorded thereon, the program including instructions that causes a computer to carry out:
a configuration evaluation step of outputting, using a learning model, evaluation values of configuration elements of a computer system, and further outputting an evaluation value of the entire computer system obtained by integrating the output evaluation values; and
a configuration element learning step of trialing design of the computer system based on preset requirements, determining, with respect to configurations obtained throughout the designing from start to finish, whether or not configuration elements included in the configurations are concretized according to the requirements, generating training data for the learning model based on a determination result, and executing machine learning on the learning model using the generated training data.

### (Supplementary Note 12)

The computer readable recording medium according to supplementary note 11,
wherein in the configuration element learning step, determining whether or not the configuration elements included in each of the configurations are concretized according to the requirements, calculating rewards to be given to the configuration elements included in the corresponding configuration, based on a determination result, and generating, for each of the configurations, the configuration and the rewards to be given to the configuration elements calculated for the configuration, as the training data.

### (Supplementary Note 13)

The computer readable recording medium according to supplementary note 11,
wherein in the configuration element learning step, generating a curriculum based on a dependence relationship representing a relationship between a specific configuration element and another configuration element required to concretize the specific configuration element, in a manner such that learning is performed in order of configuration elements with no dependence relationship and configuration elements with a dependence relationship for which learning is completed, and executing machine learning on the learning model in accordance with the generated curriculum.

### (Supplementary Note 14)

The computer readable recording medium according to supplementary note 11,
the program further including instructions that causes the computer to carry out:
a design step of determining, based on the evaluation values of the configuration elements output, a configuration to be searched for in a design space of the computer system, and designing a system configuration of the computer system using the determined configuration.

### (Supplementary Note 15)

The computer readable recording medium according to supplementary note 14,
the program further including instructions that causes the computer to carry out:
a narrowing step of determining configuration elements to be concretized, based on the evaluation values of the configuration elements output, and generating only a configuration obtained by concretizing the determined configuration elements,
wherein, in the design step, when adding the configuration to be searched for, adding only the configuration generated, and
in the configuration element learning step, in the trialing of design of the computer system, determining a configuration to be searched for in the design space of the computer system, trialing design of the system configuration of the computer system using the determined configuration, and adding, when adding the configuration to be searched for, only the configuration generated.

Although the invention of the present application has been described above with reference to the example embodiment, the invention of the present application is not limited to the above-described example embodiment. Various changes that can be understood by a person skilled in the art within the scope of the invention of the present application can be made to the configuration and the details of the invention of the present application.

### INDUSTRIAL APPLICABILITY

The present disclosure can be suitably applied to reinforcement learning aimed at acquiring efficient procedures for intellectual work such as design process of an IT system.

### REFERENCE SIGNS LIST

1 System configuration evaluation apparatus
11 Configuration evaluation unit
111 Configuration element evaluation unit
112 Configuration comprehensive evaluation unit
12 Configuration element learning unit
121 Learning process control unit
122 Design trial unit
123 Concretization success determination unit
124 Reward generation unit
125 Raining data generation unit
126 Machine learning unit
2 System configuration evaluation apparatus
21 Configuration evaluation unit
22 Configuration element learning unit
221 Learning process control unit
227 Curriculum generation unit
3 System configuration evaluation apparatus
31 Configuration evaluation unit
32 Configuration element learning unit
33 Design unit
4 System configuration evaluation apparatus
41 Configuration evaluation unit
42 Configuration element learning unit
422 Design trial unit
43 Design unit
44 Narrowing unit
510 Computer
511 CPU
512 Main memory
513 Storage device
514 Input interface
515 Display controller
516 Data reader/writer
517 Communication interface
518 Input device
519 Display device
520 Recording medium
521 Bus

What is claimed is:

1. A system configuration evaluation apparatus comprising:
at least one memory storing instructions; and
at least one processor configured to execute the instructions to:
output, using a learning model, evaluation values of configuration elements of a computer system, and further output an evaluation value of the entire computer system obtained by integrating the output evaluation values; and
trial design of the computer system based on preset requirements, determine, with respect to configurations obtained throughout the designing from start to finish, whether or not configuration elements included in the configurations are concretized according to the requirements, generate training data for the learning model based on a determination result, and execute machine learning on the learning model using the generated training data.

2. The system configuration evaluation apparatus according to claim 1,
wherein the processor further:
determines whether or not the configuration elements included in each of the configurations are concretized according to the requirements, calculates rewards to be given to the configuration elements included in the corresponding configuration, based on a determination result, and generates, for each of the configurations, the configuration and the rewards to be given to the configuration elements calculated for the configuration, as the training data.

3. The system configuration evaluation apparatus according to claim 1,
wherein the processor further:
generates a curriculum based on a dependence relationship representing a relationship between a specific configuration element and another configuration element required to concretize the specific configuration element, in a manner such that learning is performed in order of configuration elements with no dependence relationship and configuration elements with a dependence relationship for which learning is completed, and executes machine learning on the learning model in accordance with the generated curriculum.

4. The system configuration evaluation apparatus according to claim 1,
wherein the processor further:
determines, based on the evaluation values of the configuration elements output, a configuration to be searched for in a design space of the computer system, and designs a system configuration of the computer system using the determined configuration.

5. The system configuration evaluation apparatus according to claim 4,
wherein the processor further:
determines configuration elements to be concretized, based on the evaluation values of the configuration elements output, and generates only a configuration obtained by concretizing the determined configuration elements,
when adding the configuration to be searched for, adds only the configuration generated, and
determines, in the trialing of design of the computer system, a configuration to be searched for in the design space of the computer system, trials design of the system configuration of the computer system using the determined configuration, and adds, when adding the configuration to be searched for, only the configuration generated.

6. A system configuration evaluation method comprising:
outputting, using a learning model, evaluation values of configuration elements of a computer system, and further outputting an evaluation value of the entire computer system obtained by integrating the output evaluation values; and
trialing design of the computer system based on preset requirements, determining, with respect to configurations obtained throughout the designing from start to finish, whether or not configuration elements included in the configurations are concretized according to the requirements, generating training data for the learning model based on a determination result, and executing machine learning on the learning model using the generated training data.

7. The system configuration evaluation method according to claim 6,
wherein in the learning, determining whether or not the configuration elements included in each of the configurations are concretized according to the requirements, calculating rewards to be given to the configuration elements included in the corresponding configuration, based on a determination result, and generating, for each of the configurations, the configuration and the rewards to be given to the configuration elements calculated for the configuration, as the training data.

8. The system configuration evaluation method according to claim 6,
wherein in the learning, generating a curriculum based on a dependence relationship representing a relationship between a specific configuration element and another configuration element required to concretize the specific configuration element, in a manner such that learning is performed in order of configuration elements with no dependence relationship and configuration elements with a dependence relationship for which learning is completed, and executing machine learning on the learning model in accordance with the generated curriculum.

9. The system configuration evaluation method according to claim 6, further includes:
determining, based on the evaluation values of the configuration elements output, a configuration to be searched for in a design space of the computer system, and designing a system configuration of the computer system using the determined configuration.

10. The system configuration evaluation method according to claim 9, further includes:
determining configuration elements to be concretized, based on the evaluation values of the configuration elements output, and generating only a configuration obtained by concretizing the determined configuration elements,
wherein, when adding the configuration to be searched for, in the designing, adding only the configuration generated, and
in the learning, in the trialing of design of the computer system, determining a configuration to be searched for in the design space of the computer system, trialing design of the system configuration of the computer system using the determined configuration, and adding, when adding the configuration to be searched for, only the configuration generated.

11. A non-transitory computer readable recording medium that includes a program recorded thereon, the program including instructions that causes a computer to carry out the steps of:
outputting, using a learning model, evaluation values of configuration elements of a computer system, and further outputting an evaluation value of the entire computer system obtained by integrating the output evaluation values; and
trialing design of the computer system based on preset requirements, determining, with respect to configurations obtained throughout the designing from start to finish, whether or not configuration elements included in the configurations are concretized according to the requirements, generating training data for the learning model based on a determination result, and executing machine learning on the learning model using the generated training data.

12. The non-transitory computer readable recording medium according to claim 11,
wherein in the learning, determining whether or not the configuration elements included in each of the configurations are concretized according to the requirements, calculating rewards to be given to the configuration elements included in the corresponding configuration, based on a determination result, and generating, for each of the configurations, the configuration and the rewards to be given to the configuration elements calculated for the configuration, as the training data.

13. The non-transitory computer readable recording medium according to claim 11,
wherein in the learning, generating a curriculum based on a dependence relationship representing a relationship between a specific configuration element and another configuration element required to concretize the specific configuration element, in a manner such that learning is performed in order of configuration elements with no dependence relationship and configuration elements with a dependence relationship for which learning is completed, and executing machine learning on the learning model in accordance with the generated curriculum.

14. The non-transitory computer readable recording medium according to claim 11,
the program further including instructions that causes the computer to carry out:
determining, based on the evaluation values of the configuration elements output, a configuration to be searched for in a design space of the computer system, and designing a system configuration of the computer system using the determined configuration.

15. The non-transitory computer readable recording medium according to claim 14,
the program further including instructions that causes the computer to carry out:
determining configuration elements to be concretized, based on the evaluation values of the configuration elements output, and generating only a configuration obtained by concretizing the determined configuration elements,
wherein, in the designing, when adding the configuration to be searched for, adding only the configuration generated, and
in the learning, in the trialing of design of the computer system, determining a configuration to be searched for in the design space of the computer system, trialing design of the system configuration of the computer system using the determined configuration, and adding, when adding the configuration to be searched for, only the configuration generated.
